(19) United States
(12) Patent Application Publication
(10) Pub. No.: US 2026/0047310 A1
(43) Pub. Date: Feb. 12, 2026

(54) DISPLAY DEVICE, ELECTRONIC DEVICE, AND METHOD FOR MANUFACTURING THE DISPLAY DEVICE

(71) Applicant: Samsung Display Co., Ltd., Yongin-si (KR)

(72) Inventor: JUNGWOOK LEE, Yongin-si (KR)

(21) Appl. No.: 19/235,441

(22) Filed: Jun. 11, 2025

(30) Foreign Application Priority Data
Aug. 8, 2024 (KR) 10-2024-0106257

(51) Int. Cl. H10K 59/50; G02F 1/155; H10K 59/12; H10K 59/122

(52) U.S. Cl. CPC H10K 59/50; G02F 1/155; H10K 59/1201; H10K 59/122

(57) ABSTRACT

Disclosed is a display device including a light emitting element layer including a light emission area, and a non-light emission area around the light emission area, and an optical path control layer on the light emitting element layer, and that controls a path of light provided from the light emitting element layer, the optical path control layer may include at least one control pattern. The control pattern includes an electrode structure that overlaps the non-light emission area, does not overlap the light emission area, and in which a cavity is defined in an interior thereof, and a filling pattern filled in the cavity, and including an electrochromic material.

### CROSS-REFERENCE TO RELATED APPLICATION

The present application claims priority to and the benefit of Korean Patent Application No. 10-2024-0106257, filed on Aug. 8, 2024, in the Korean Intellectual Property Office, the entire content of which is hereby incorporated by reference.

### BACKGROUND

Embodiments of the present disclosure described herein relate to a display device, an electronic device and a method for manufacturing the display device, and for example, relate to a display device and an electronic device that may maintain a high resolution and a high luminance while being operated in various suitable modes, and a manufacturing method thereof.

Display devices used in various suitable devices, such as televisions, mobile phones, tablets, and vehicles, are being developed. According to a usage environment, in which information has to be protected, or regulations for safety, a limitation of a viewing angle of a display device is useful or required. Accordingly, research is being conducted to limit the viewing angle.

### SUMMARY

Embodiments of the present disclosure provide a display device and an electronic device that may be operated in various suitable modes, and a method for manufacturing the same.

According to an embodiment, a display device includes a light emitting element layer including a light emission area, and a non-light emission area around (e.g., surrounding) the light emission area, and an optical path control layer on the light emitting element layer, and that controls a path of light provided from the light emitting element layer, the optical path control layer may include at least one control pattern, and the control pattern includes an electrode structure that overlaps the non-light emission area, does not overlap the light emission area, and in which a cavity is defined in an interior thereof, and a filling pattern filled in the cavity, and including an electrochromic material.

The electrode structure may include a first transparent electrode provided at a lower portion of the cavity, and a second transparent electrode around (e.g., surrounding) an upper portion and a side portion of the cavity.

The filling pattern may further include an electrolyte, in which the electrochromic material is dispersed.

The optical path control layer may further include an overcoat layer on the control pattern, and that covers an upper portion of the control pattern.

The control pattern may include a first layer control pattern on the light emitting element layer, a second layer control pattern on the first layer control pattern, and a third layer control pattern on the second layer control pattern.

The first layer control pattern may include a first layer electrode structure, in which a first cavity is defined, and a first layer filling pattern filled in the first cavity and including an electrochromic material, the second layer control pattern may include a second layer electrode structure, in which a second cavity is defined, and a second layer filling pattern filled in the second cavity and including an electrochromic material, and the third layer control pattern may include a third layer electrode structure, in which a third cavity is defined, and a third layer filling pattern filled in the third cavity and including an electrochromic material.

The first layer control pattern may include a first power source provided to the first layer electrode structure, the second layer control pattern may include a second power source provided to the second layer electrode structure, the third layer control pattern may include a third power source provided to the third layer electrode structure, and the first power source, the second power source, and the third power source may be distinguished from each other to be driven separately.

The control pattern may include a first control pattern and a second control pattern spaced apart from each other in one direction with the light emission area therebetween.

A spacing distance between the first control pattern and the second control pattern in the one direction may be greater than or equal to a width of the light emission area in the one direction.

The display device may be driven to be selectively operated in any one selected from among a first mode and a second mode, in the first mode, a separate voltage may not be applied to the electrode structure, and in the second mode, a first power source may be applied to the electrode structure.

In the first mode, the control pattern may transmit the light provided from the light emitting element layer, and in the second mode, the control pattern may shield the light provided from the light emitting element layer.

The electrochromic material may include at least one selected from among a metal oxide, a metal chloride, and a graphene quantum dot.

The light emitting element layer may include a pixel definition layer, in which a pixel opening that defines the light emission area is defined, and a light emission layer, at least a portion of which is provided in the pixel opening, and that provides the light, and the control pattern may overlap the pixel definition layer on a plane (e.g., in a plan view).

The light emission area may include a first light emission area that emits light of a first wavelength, a second light emission area that emits light of a second wavelength being different from the first wavelength, and a third light emission area that emits light of a third wavelength being different from the first wavelength and the second wavelength, and the control pattern may overlap between the first light emission area and the second light emission area, and between the second light emission area and the third light emission area on a plane (e.g., in a plan view).

The display device may further include an input sensor between the optical path control layer and the light emitting element layer.

The optical path control layer may be directly on the input sensor.

According to an embodiment, an electronic device includes a light emitting element layer including a light emission area, and a non-light emission area around (e.g., surrounding) the light emission area, and an optical path control layer on the light emitting element layer, the optical path control layer includes at least one control pattern, and an overcoat layer that covers an upper portion of the control pattern, and the control pattern includes an electrode structure that overlaps the non-light emission area, and in which a cavity is defined in an interior thereof, and a filling pattern filled in the cavity, and including an electrochromic material.

According to an embodiment, a method for manufacturing a display device includes forming a light emitting element layer, and forming an optical path control layer on the light emitting element layer, the forming of the optical path control layer includes forming a first transparent electrode through a conductive material, forming a sacrificial layer on the first transparent electrode through an organic material, forming a second transparent electrode on the sacrificial layer, forming a cavity structure between the first transparent electrode and the second transparent electrode by removing the sacrificial layer, and filling an electrochromic material in the cavity structure.

The forming of the optical path control layer may further include forming an overcoat layer by providing an organic material on the second transparent electrode.

In the filling of the electrochromic material, the electrochromic material may be dispersed in an electrolyte to be filled in the cavity structure through a capillary phenomenon.

### BRIEF DESCRIPTION OF THE DRAWINGS

The above and other objects and features of embodiments of the present disclosure will become apparent by describing in more detail embodiments thereof with reference to the accompanying drawings.

FIG. 1A is a front view of an electronic device according to an embodiment of the present disclosure.

FIG. 1B is a perspective view of a display device according to an embodiment of the present disclosure.

FIG. 2A is a view illustrating an interior of a vehicle, in which a display device according to an embodiment of the present disclosure is disposed.

FIG. 2B is a view illustrating an image that is visually recognized from a driver's seat when a display device according to an embodiment of the present disclosure is operated in a second mode.

FIGS. 3A and 3B are cross-sectional views of a display device according to an embodiment of the present disclosure.

FIG. 4 is a block diagram of a display device according to an embodiment of the present disclosure.

FIG. 5 is an enlarged plan view illustrating a portion of a display device according to an embodiment of the present disclosure.

FIG. 6A is a graph depicting luminance depending on a viewing angle when a display device according to an embodiment is operated in a first mode.

FIG. 6B is a graph depicting luminance depending on a viewing angle when a display device according to an embodiment is operated in a second mode.

FIG. 7 is a cross-sectional view of a display device according to an embodiment of the present disclosure.

FIG. 8 is a cross-sectional view of a display device according to an embodiment of the present disclosure.

FIG. 9A is a cross-sectional view illustrating a display device according to an embodiment of the present disclosure when it is operated in a first mode.

FIG. 9B is a cross-sectional view illustrating a display device according to an embodiment of the present disclosure when it is operated in a second mode.

FIG. 10 is a cross-sectional view of a display device according to an embodiment of the present disclosure.

FIG. 11A is a flowchart of a method for manufacturing a display device according to an embodiment of the present disclosure.

FIG. 11B is a flowchart of some operations in a method for manufacturing a display device according to an embodiment of the present disclosure.

FIGS. 12A to 12E are cross-sectional views of some operations in a method for manufacturing a display device according to an embodiment of the present disclosure.

### DETAILED DESCRIPTION

In the specification, when it is mentioned that a component (or an area, a layer, a part, or the like) is “on”, “connected to”, or “coupled to” another component, it means that the former component may be directly on, connected to, or coupled to the latter component or a third component may be between the components.

In the specification, the expression of “directly provided” may mean that none of a layer, a film, an area, and a plate is added between a part, such as the layer, the film, the area, and the plate, and another part. For example, the expression of “directly provided” may mean that the two layers or two members are provided while an additional member, such as an adhesive member, is not used therebetween.

The same reference numerals denote the same components. Furthermore, in the drawings, thicknesses, ratios, dimensions of the components may be exaggerated for an effective description of the technical contents. The term “and/or” includes one or more combinations that may be defined by the associated components.

Furthermore, in describing the various components, the terms, such as first and second may be used, but the present disclosure is not limited by the terms. The terms are simply used to distinguish the components. For example, a first component may be named a second component, and similarly the second component also may be named the first component while not departing from the scope of the present disclosure. A singular expression includes a plural expression unless an exemption is explicitly described in the context.

Furthermore, the terms, such as “under”, “below”, “on”, and “above”, are used to describe an associative relationship between the components illustrated in the drawings. The terms are relative concepts, and are described with respect to directions indicated in the drawings.

When the terms, such as “comprise” and/or “comprising”, is used in the specification, it should be understood that they specify presence of the above-mentioned features, numbers, steps, operations, components, parts, and/or combinations thereof, and do not exclude presence or addition of one or more other numbers, steps, operations, components, parts, and/or combinations thereof.

Unless otherwise defined, all terms, including technical and scientific terms, used herein have the same meaning as commonly understood by those skilled in the art to which the present disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, embodiments of the present disclosure will be described with reference to the drawings.

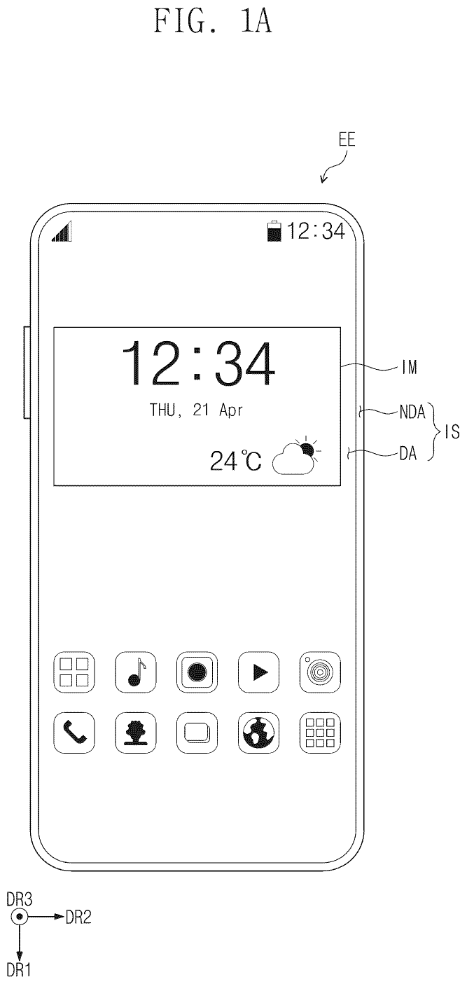

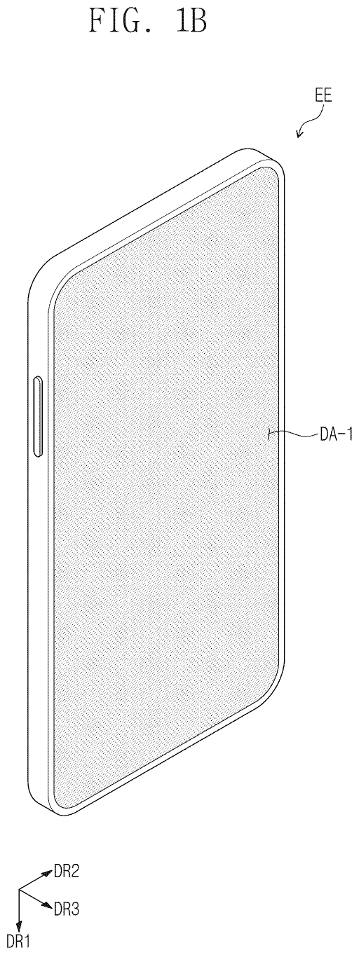

FIG. 1A is a front view of an electronic device EE according to an embodiment of the present disclosure. FIG. 1B is a perspective view of the electronic device EE according to an embodiment of the present disclosure.

Referring to FIGS. 1A and 1B, the electronic device EE may be a device that is activated in response to an electrical signal. The electronic device EE may be applied to various suitable electronic devices, such as mobile phones, tablets, smart watches, laptops, computers, vehicle display, and/or smart televisions.

The electronic device EE may display an image on a display surface IS that is parallel to a first direction DR1 and a second direction DR2. The display surface IS, on which the image is displayed, may correspond to a front surface of the electronic device EE. The image may include a still image as well as a dynamic image (e.g., a moving image). A normal direction of the display surface IS, for example, a thickness direction of the electronic device EE, is indicated by a third direction DR3. A front surface (or an upper surface) and a rear surface (or a lower surface) of each layer or unit that will be further described herein below are distinguished by the third direction DR3.

The display surface IS of the electronic device EE may be divided into a display area DA and a non-display area NDA. The display area DA may be an area, in which an image is displayed. The user visually recognizes the image through the display area DA. In an embodiment, it is illustrated that the display area DA has a rectangular shape having rounded corners. However, this is illustrated by way of example, and the display area DA may have various suitable shapes, and the present disclosure is not limited to any one embodiment.

The non-display area NDA is adjacent to the display area DA. The non-display area NDA may have a set or specific color. The non-display area NDA may be around (e.g., surround) the display area DA. Accordingly, the shape of the display area DA may be substantially defined by the non-display area NDA. However, this is illustrated by way of example, and the non-display area NDA may be provided adjacent to only one side of the display area DA or may be omitted. The electronic device EE according to an embodiment of the present disclosure may include various suitable embodiments, and the present disclosure is not limited to any one embodiment.

FIG. 1A may be a front view of the electronic device EE that is operated in a first mode or a second mode. FIG. 1B may be a side perspective view of the electronic device EE that is operated in the second mode. For example, the first mode may be a normal mode to display a screen at a first viewing angle, and the second mode may be a viewing angle control mode to display a screen at a second viewing angle that is narrower than the first viewing angle. The second mode may be referred to as a privacy mode, and/or the like. The first viewing angle and the second viewing angle may be defined as angles, at which an image may be viewed without distortion with respect to a normal direction of the display surface IS.

Referring to FIG. 1A, in the first mode or the second mode, when the electronic device EE is viewed from a front side (or a direction that is parallel (e.g., substantially parallel) to the normal direction or the third direction DR3), images IM generated by the electronic device EE may be visually recognized by the user. In the second mode, when the electronic device EE is viewed at an angle that exceeds the second viewing angle, the images IM may not be visually recognized. For reference, when the electronic device EE is viewed at an angle that exceeds the second viewing angle in the first mode, the user may visually recognize the images IM.

The second viewing angle in the second mode, and a luminance at the second viewing angle may be variously, suitably set. For example, the second viewing angle may be 45°, and a luminance at 45° may be 10% of a maximum luminance, but the present disclosure is not particularly limited.

The electronic device EE may be selectively operated in any one selected from among the first mode to display a screen at the first viewing angle and the second mode to display a screen at the second viewing angle that is narrower than the first viewing angle. Switching between the first mode and the second mode may be set by the user, or the first mode may be switched to the second mode when a set or specific application is executed or used. For example, when an application at the risk of exposure of personal information, for example, in a bank and/or memo application, is executed or used, the electronic device EE may be switched from the first mode to the second mode.

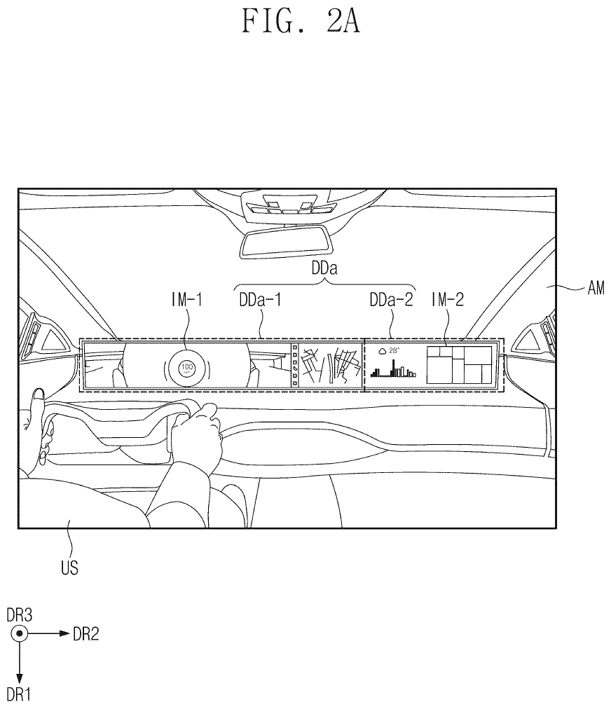

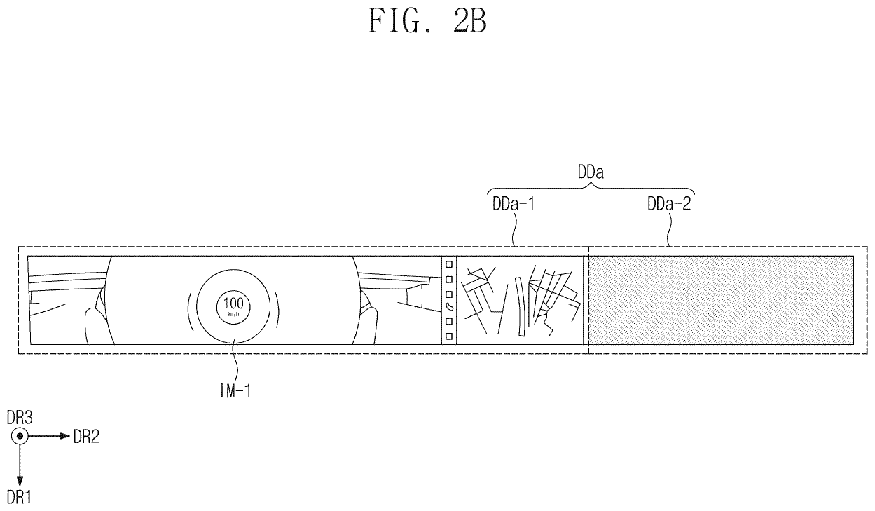

FIG. 2A is a view illustrating an interior of a vehicle AM, in which a display device DDa according to an embodiment of the present disclosure is provided. FIG. 2B is a view illustrating an image that is visually recognized from a driver's seat when the display device DDa according to an embodiment of the present disclosure is operated in the second mode.

Referring to FIG. 2A, the display device DDa may be provided in an interior of the vehicle AM. The display device DDa may be provided in an interior of the vehicle AM to provide various suitable information to the driver US. The display device DDa may include a first display device DDa-1 and a second display device DDa-2. The first display device DDa-1 may provide a first image IM-1 that is useful or required to drive to the driver US. The second display device DDa-2 may be provided at a position that faces a passenger seat, and the second display device DDa-2 may provide a second image IM-2. For example, the first image IM-1 may display speed information, vehicle state information, vehicle internal manipulation information, navigation information, and/or the like, and the second image IM-2 may display various suitable information that is related to driving, as well as information that is useful or necessary to drive.

In an embodiment of the present disclosure, the first display device DDa-1 and the second display device DDa-2 may be separate display devices or one display device including one panel. In embodiments of separate display devices, the first display device DDa-1 may not include an operation of controlling a viewing angle, and the second display device DDa-2 may be operated in the first mode or in the second mode. When the first display device DDa-1 and the second display device DDa-2 are one display device DDa, both the first display device DDa-1 and the second display device DDa-2 may be operated in the first mode or may be operated in the second mode. In embodiments, only the second display device DDa-2 may be partially operated in the first mode or the second mode.

The first mode may be a normal mode to display a screen at a first viewing angle, and the second mode may be a viewing angle control mode to display a screen at a second viewing angle that is narrower than the first viewing angle. The second viewing angle in the second mode, and a luminance at the second viewing angle may be variously, suitably set. For example, the second viewing angle and the luminance at the second viewing angle may be set according to a rule for each country, in which the vehicle AM is driven. For example, the second viewing angle may be 35 degrees, and the luminance at 35 degrees may be 0.75% of the maximum luminance, but the present disclosure is not particularly limited.

Referring to FIG. 2B, an image that is visually recognized by the driver US who is driving is illustrated. The driver US may view only a first image IM-1 that is useful or required to drive, and a second image IM-2 (see FIG. 2A) that may display unnecessary information to drive cannot be viewed due to limitations on the viewing angles.

The switching between the first mode and the second mode may be changed depending on whether the vehicle AM is driven or stopped. For example, when the vehicle AM is driven, at least the second display device DDa-2 may be operated in the second mode. When the vehicle AM is stopped, the second display device DDa-2 may be operated in the first mode. In embodiments, even when the vehicle AM is driven, the second display device DDa-2 may be operated in the first mode when the vehicle AM is in an autonomous driving mode. In the first mode, the driver US may view the first image IM-1 illustrated in FIG. 2A.

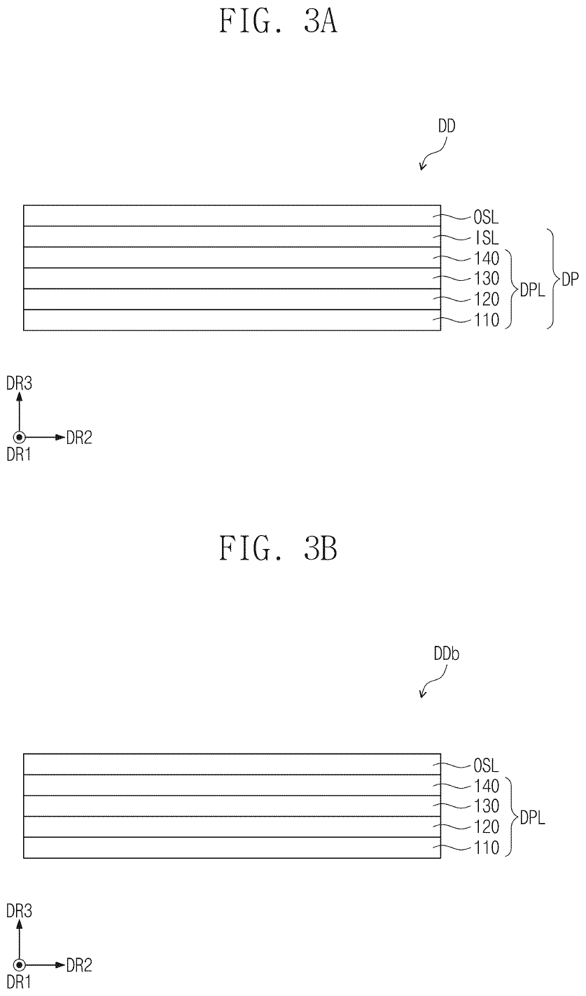

FIG. 3A is a cross-sectional view of a display device DD according to an embodiment of the present disclosure. The display device DD illustrated in FIG. 3A or below may be the display device DDa illustrated in FIG. 2A, or may be applied to the electronic device EE illustrated in FIG. 1A.

Referring to FIG. 3A, the display device DD may include a display panel DP and an optical path control layer OSL. A protective film, a window, and/or a functional coating layer that provides a front surface of the display device DD may be further on the optical path control layer OSL.

The display panel DP may include a display layer DPL and an input sensor ISL.

The display layer DPL may include a base layer 110, a circuit layer 120, a light emitting element layer 130, and an encapsulation layer 140. The display layer DPL may be a configuration that substantially generates an image. The display layer DPL may be a light emitting display layer, and for example, may be an organic light emitting display layer, an inorganic light emitting display layer, an organic-inorganic light emitting display layer, a quantum dot display layer, a micro LED display layer, and/or a nano LED display layer.

The input sensor ISL may sense an external input that is applied from the outside. The external input may be an input by the user. The input by the user may include various suitable types (or kinds) of external inputs, such as a portion of the body of the user, light, heat, a pen, and/or a pressure. The input sensor ISL may be referred to as a sensor, an input sensing layer, and/or an input sensing panel. The input sensor ISL may be formed through a continuous (e.g., substantially continuous) process with the display layer DPL, and may be provided directly on the display layer DPL. However, the present disclosure is not particularly limited thereto. For example, the input sensor ISL may be coupled to the display layer DPL through an adhesive layer.

The optical path control layer OSL may control a path of light that is provided from the display layer DPL. The optical path control layer OSL may include a structure to control a path of light. The optical path control layer OSL may be on the input sensor ISL. The optical path control layer OSL may be formed through a continuous (e.g., substantially continuous) process with the display layer DPL and the input sensor ISL, and may be provided directly on the input sensor ISL. However, the present disclosure is not particularly limited thereto. For example, the optical path control layer OSL may be coupled to the input sensor ISL through an adhesive layer.

FIG. 3B is a cross-sectional view of a display device DDb according to an embodiment of the present disclosure.

Referring to FIG. 3B, the display device DDb may include a display layer DPL and an optical path control layer OSL. Compared with the illustration of FIG. 3A, the display device DDb may not include an input sensor ISL (see FIG. 3A). The optical path control layer OSL may be formed through a continuous (e.g., substantially continuous) process with the display layer DPL, and may be provided directly on the display layer DPL. However, the present disclosure is not particularly limited thereto.

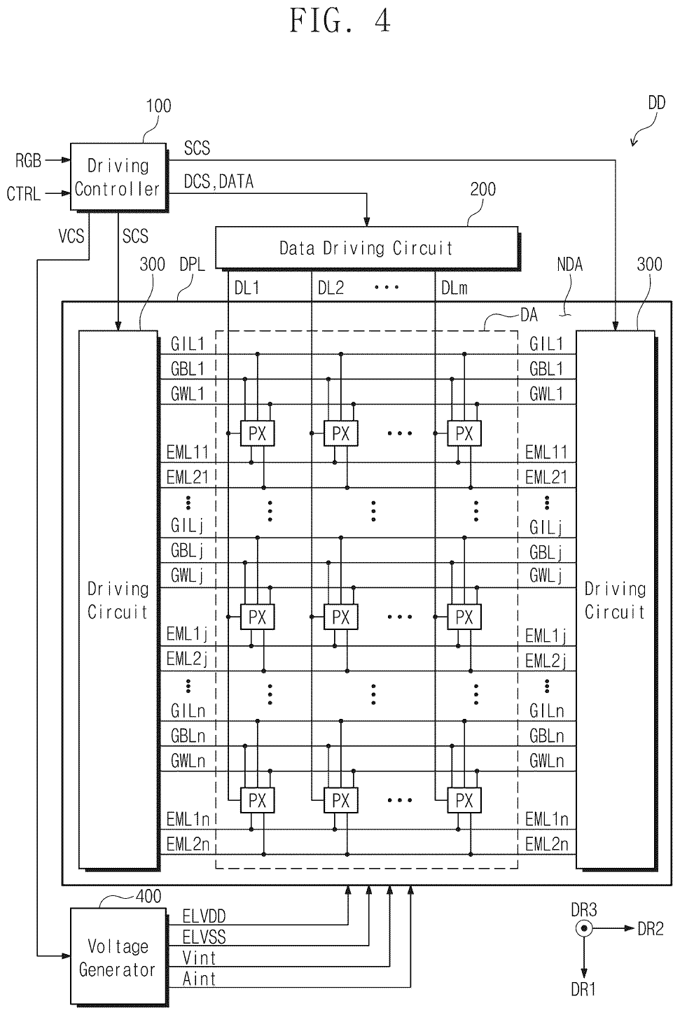

FIG. 4 is a block diagram of a display device DD according to an embodiment of the present disclosure.

Referring to FIG. 4, the display device DD may further include a driving controller 100 to drive the display layer DPL and a panel driver. As an example embodiment of the present disclosure, the panel driver may include a data driving circuit 200 (or a data driver), driving circuits 300, and a voltage generator 400.

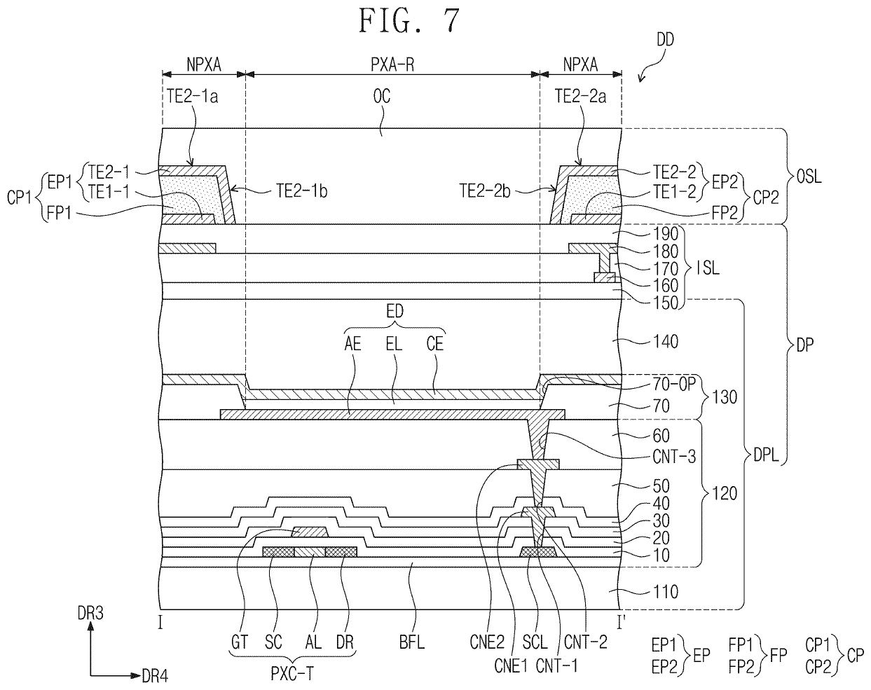

The display layer DPL may include a display area DA and a non-display area NDA. The display layer DPL may include a plurality of pixels PX that are provided in the display area DA. Each of the plurality of pixels PX includes a light emitting element ED (see FIG. 7) and a pixel driving circuit that controls light emission of the light emitting element ED. The pixel driving circuit PXC may include one or more transistors and one or more capacitors.

The display layer DPL may further include initialization scan lines GIL1 to GILn, write scan lines GWL1 to GWLn, black scan lines GBL1 to GBLn, first light emission control lines EML11 to EML1n, second light emission control lines EML21 to EML2n, and data lines DL1 to DLm. In an embodiment of the present disclosure, the display layer DPL may further include other third light emission control lines.

The driving controller 100 receives an image signal RGB and a control signal CTRL. The driving controller 100 generates an image data signal DATA that is obtained by converting a data format of the image signal RGB according to a specification of an interface with the data driving circuit 200. The driving controller 100 may output a first control signal SCS, a second control signal DCS, and a third control signal VCS.

The data driving circuit 200 receives a second control signal DCS and an image data signal DATA from the driving controller 100. The data driving circuit 200 converts the image data signal DATA into data signals, and outputs the data signals to the data lines DL1 to DLm. The data signals are analog voltages corresponding to a gray value of the image data signal DATA. The data lines DL1 to DLm may be arranged along the second direction DR2, and each of the data lines DL1 to DLm may extend along the first direction DR1.

The driving circuit 300 may be provided in the non-display area NDA of the display layer DPL, but the present disclosure is not particularly limited thereto. For example, at least a portion of the driving circuit 300 may be provided in the display area DA. The driving circuits 300 may include transistors that are formed through the same process as that of the pixel driving circuit PXC (see FIG. 14).

The driving circuit 300 may receive a first control signal SCS, and may output a scan signal or a light emission control signal to the initialization scan lines GIL1 to GILn, the write scan lines GWL1 to GWLn, the black scan lines GBL1 to GBLn, the first light emission control lines EML11 to EML1n, and the second light emission control lines EML21 to EML2n.

A plurality of driving circuits 300 may be provided. For example, the plurality of driving circuits 300 may be spaced apart from each other with the display area DA therebetween. The initialization scan lines GIL1 to GILn, the write scan lines GWL1 to GWLn, the black scan lines GBL1 to GBLn, the first light emission control lines EML11 to EML1n, and the second light emission control lines EML21 to EML2n may be electrically connected to the driving circuits 300 to receive signals from the driving circuits 300, respectively. For example, one initialization scan line GIL1, one write scan line GWL1, one black scan line GBL1, one first light emission control line EML11, and one second light emission control line EML21 may receive the same signal from two driving circuits 300. However, this is only an example, and one of the two driving circuits 300 illustrated in FIG. 4 may be omitted.

Each of the driving circuits 300 may include initialization scan lines GIL1 to GILn, write scan lines GWL1 to GWLn, a scan driving circuit that is connected to the black scan lines GBL1 to GBLn, and a light emission control driving circuit that is connected to first light emission control lines EML11 to EML1n and the second light emission control lines EML21 to EML2n. In an embodiment of the present disclosure, the scan driving circuit and the light emission control driving circuit may be spaced apart from each other with the display area DA therebetween.

Each of the initialization scan lines GIL1 to GILn, the write scan lines GWL1 to GWLn, the black scan lines GBL1 to GBLn, the first light emission control lines EML11 to EML1n, and the second light emission control lines EML21 to EML2n may extend in the second direction DR2, and the initialization scan lines GIL1 to GILn, the write scan lines GWL1 to GWLn, and the black scan lines GBL1 to GBLn, the first light emission control lines EML11 to EML1n, and the second light emission control lines EML21 to EML2n may be spaced apart from each other in the first direction DR1.

Each of the pixels PX may be electrically connected to three scan lines, two light emission control lines, and one data line. For example, as illustrated in FIG. 4, the pixels in the first row may be connected to scan lines GIL1, GWL1, and GBL1 and the first and second light emission control lines EML11 and EML21. The pixels in the first column may be connected to the data line DL1. Furthermore, the pixels in the j-th row may be connected to scan lines GILj, GWLj, and GBLj, and the first and second light emission control lines EML1j and EML2j.

The voltage generator 400 generates voltages that are useful or required for an operation of the display panel DP. In an embodiment, the voltage generator 400 may generate a first driving voltage ELVDD, a second driving voltage ELVSS, a first initialization voltage Vint, and a second initialization voltage Aint.

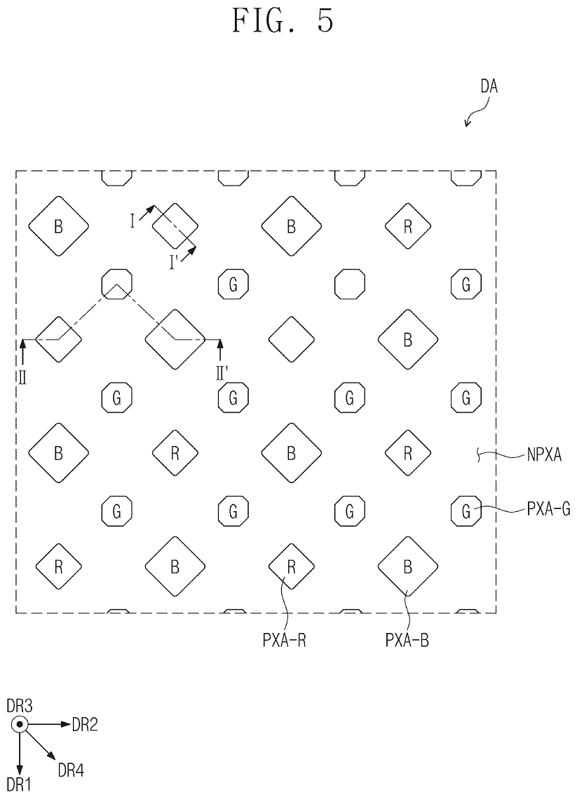

FIG. 5 is an enlarged plan view illustrating a portion of a display device DD (see FIG. 4) according to an embodiment of the present disclosure. FIG. 5 illustrates a plane of the display device DD, viewed from the display area DA (see FIG. 4) of the display layer DPL (see FIG. 4), and illustrates an arrangement of a plurality of light emission areas PXA-R, PXA-G, and PXA-B.

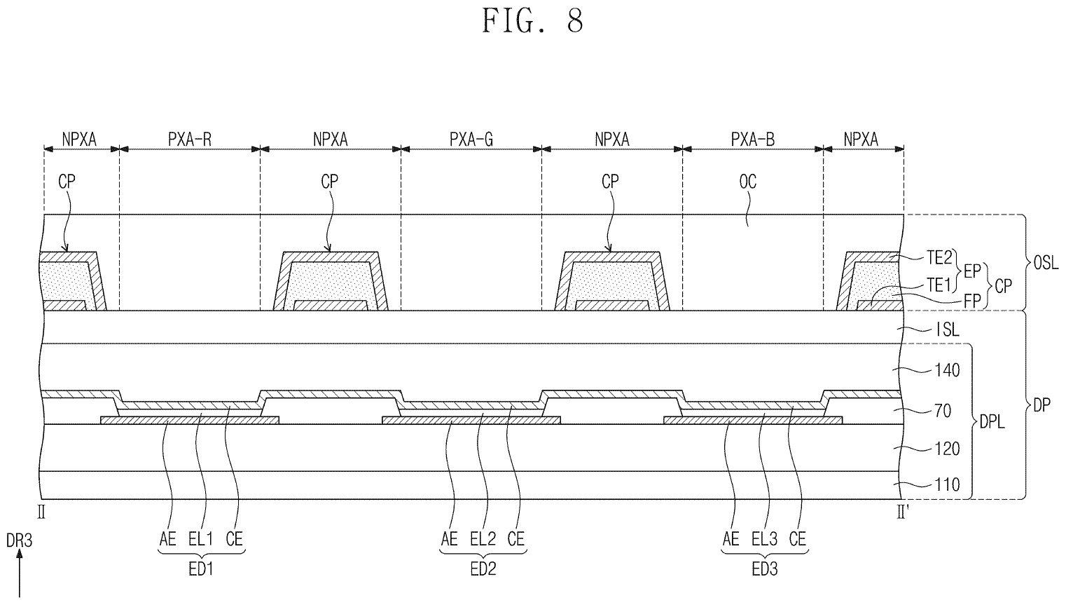

Referring to FIG. 5, the display area DA may include first to third light emission areas PXA-R, PXA-G, and PXA-B and a non-light emission area NPXA that is around (e.g., surrounds) the first to third light emission areas PXA-R, PXA-G, and PXA-B. The first to third light emission areas PXA-R, PXA-G, and PXA-B may correspond to areas, in which light provided from light emitting elements ED1, ED2, and ED3, and FIG. 8 is emitted, respectively. The first to third light emission areas PXA-R, PXA-G, and PXA-B may be classified according to colors of the light emitted toward the outside of the display device DD (see FIG. 4).

The first to third light emission areas PXA-R, PXA-G, and PXA-B may provide first to third color lights having different colors, respectively. For example, the first color light may be a red light, the second color light may be a green light, and the third color light may be a blue light. However, examples of the first to third color lights are not necessarily limited to the above example.

Each of the first to third light emission areas PXA-R, PXA-G, and PXA-B may be defined as an area, in which an upper surface of an anode is exposed by a light emitting opening that will be further described herein. The non-light emission area NPXA may set boundaries between the first to third light emission areas PXA-R, PXA-G, and PXA-B, and may prevent or reduce mixing of colors between the first to third light emission areas PXA-R, PXA-G, and PXA-B.

Each of the first to third light emission areas PXA-R, PXA-G, and PXA-B may be provided in plural, and may be repeatedly provided in a set or specific arrangement form in the display area DA. For example, the first and third light emission areas PXA-R and PXA-B may be alternately provided along the first direction DR1 to form a ‘first group’. The second light emission areas PXA-G may be provided along the first direction DR1 to form a ‘second group’. A plurality of ‘first groups’ and a plurality of ‘second groups’ may be provided, respectively, and the ‘first groups’ and the ‘second groups’ may be alternately provided along the second direction DR2.

One second light emission area PXA-G may be spaced apart from one first light emission area PXA-R or one third light emission area PXA-B in a fourth direction DR4. The fourth direction DR4 may be defined as a direction between the first and second directions DR1 and DR2.

FIG. 5 illustrates an arrangement form of the first to third light emission areas PXA-R, PXA-G, and PXA-B by way of example, and the first to third light emission areas PXA-R, PXA-G, and PXA-B may be provided in various suitable forms without being limited thereto. In an embodiment, the first to third light emission areas PXA-R, PXA-G, and PXA-B may have a PENTILE® arrangement structure (e.g., an RGBG matrix, RGBG structure, or RGBG matrix structure) as illustrated in FIG. 5, but the present disclosure is not limited thereto. PENTILE® is a duly registered trademark of Samsung Display Co., Ltd. In embodiments, the first to third light emission areas PXA-R, PXA-G, and PXA-B may have a stripe arrangement form or a DIAMOND PIXEL™) arrangement form. DIAMOND PIXEL™ is a trademark of Samsung Display Co., Ltd.

The first to third light emission areas PXA-R, PXA-G, and PXA-B may have various suitable shapes on a plane (e.g., in a plan view). For example, the first to third light emission areas PXA-R, PXA-G, and PXA-B may have shapes, such as a polygon, a circle, or an ellipse. FIG. 5 illustrates first and third light emission areas PXA-R and PXA-B having a rectangular shape (or a rhombus shape) on a plane (e.g., in a plan view), and a second light emission area PXA-G having an octagonal shape.

The first to third light emission areas PXA-R, PXA-G, and PXA-B may have the same shape on a plane (e.g., in a plan view), or at least portions thereof may have different shapes. FIG. 5 illustrates first and third light emission areas PXA-R and PXA-B having the same shape on a plane and a second light emission area PXA-G having a different shape from those of the first and third light emission areas PXA-R and PXA-B by way of example.

At least portions of the first to third light emission areas PXA-R, PXA-G, and PXA-B may have different areas on a plane (e.g., in a plan view). In an embodiment, an extent (e.g., a size) of the first light emission area PXA-R that emits red light, may be greater than an extent (e.g., a size) of the second light emission area PXA-G that emits green light, and may be smaller than an extent (e.g., a size) of the third light emission area PXA-B that emits blue light. However, a scale relationship of the extents of the first to third light emission areas PXA-R, PXA-G, and PXA-B depending on the light emission color is not limited thereto, and may suitably vary depending on a design of the display device DD (see FIG. 4). Furthermore, the present disclosure is not limited thereto, and the first to third light emission areas PXA-R, PXA-G, and PXA-B may have the same extent (e.g., size) on a plane (e.g., in a plan view).

The shapes, the extents, and the arrangements of the first to third light emission areas PXA-R, PXA-G, and PXA-B of the display device DD (see FIG. 4) of the present disclosure may be variously, suitably designed depending on the color of the emitted light and/or the size and configuration of the display module DM (see FIG. 2), and the present disclosure is not limited to the embodiment illustrated in FIG. 5.

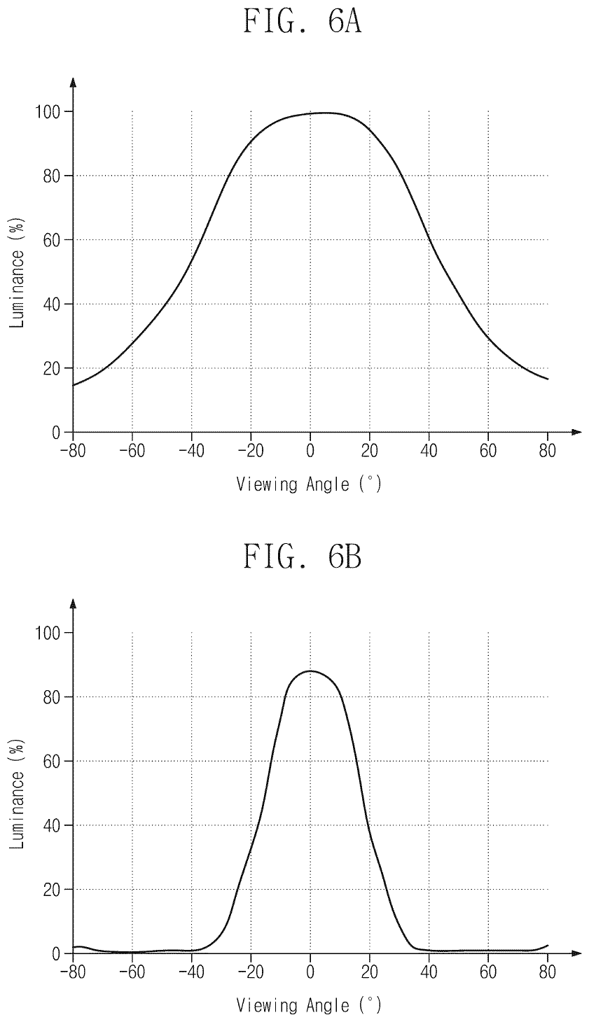

FIG. 6A is a graph depicting luminance depending on a viewing angle when a display device according to an embodiment is operated in a first mode. FIG. 6B is a graph depicting luminance depending on a viewing angle when a display device according to an embodiment is operated in a second mode.

Referring to FIGS. 5 and 6A, when the display device operates in the first mode, a luminance may be about 40% of a maximum luminance at a viewing angle of 45°. Accordingly, the image displayed by the display device DD (see FIG. 1A) may be visually recognized at a viewing angle of 45°.

Referring to FIGS. 5 and 6B, when the display device is operated in the second mode, the luminance at a viewing angle of 45° may be close to 0% of the maximum luminance. Accordingly, the image displayed by the display device DD (see FIG. 1A) may not be visually recognized at a viewing angle of 45°.

According to an embodiment of the present disclosure, the display device DD (see FIG. 1A) may be switched to the first mode and the second mode. For example, according to a user's selection or according to a set or specific regulation, the display device DD (see FIG. 1A) may be operated in the second mode, in which the viewing angle is controlled.

FIG. 7 is a cross-sectional view of a display device DD according to an embodiment of the present disclosure. FIG. 7 is a cross-sectional view corresponding to cutting line I-I′ illustrated in FIG. 5.

Referring to FIG. 7, the display layer DPL may include a base layer 110, a circuit layer 120, a light emitting element layer 130, and an encapsulation layer 140.

The base layer 110 may be a member that provides a base surface, on which the circuit layer 120 is provided. The base layer 110 may include a synthetic resin layer. The synthetic resin layer may be a polyimide-based resin layer, and a material thereof is not particularly limited. Furthermore, the base layer 110 may include a glass substrate, a metal substrate, and/or an organic/inorganic composite material substrate.

At least one inorganic layer is on the upper surface of the base layer 110. The inorganic layer may include at least one selected from among aluminum oxide, titanium oxide, silicon oxide, silicon nitride, silicon oxynitride, zirconium oxide, and hafnium oxide. The inorganic layer may be a plurality of layers. The multi-layered inorganic layers may constitute a barrier layer and/or a buffer layer. In an embodiment, it is illustrated that the display layer DPL includes a buffer layer BFL.

The buffer layer BFL may improve a bonding strength between the base layer 110 and the semiconductor pattern. The buffer layer BFL may include at least one selected from among silicon oxide, silicon nitride, and silicon oxynitride. For example, the buffer layer BFL may include a structure, in which silicon oxide layers and silicon nitride layers are alternately laminated.

The semiconductor pattern may be on the buffer layer BFL. The semiconductor pattern may include polysilicon. However, the present disclosure is not limited thereto, and the semiconductor pattern may include amorphous silicon, low-temperature polycrystalline silicon, and/or an oxide semiconductor.

FIG. 7 only illustrates some semiconductor patterns, and semiconductor patterns may be further provided in other areas. The semiconductor patterns may be provided in a set or specific rule across the pixels. The semiconductor patterns may have different electrical properties depending on whether they are doped or not. The semiconductor pattern may include a first area having a high conductivity (e.g., high electrical conductivity) and a second area having a low conductivity (e.g., low electrical conductivity). The first area may be doped with an N-type dopant or a P-type dopant. The P-type transistor may include a doped area that is doped with a P-type dopant, and the N-type transistor may include a doped area that is doped with an N-type dopant. The second area may be a non-doped area or an area that is doped with a lower concentration than that of the first area.

A conductivity (e.g., electrical conductivity) of the first area is higher than a conductivity (e.g., electrical conductivity) of the second area, and substantially, the first area may serve as an electrode or a signal line. The second area may substantially correspond to an active area (or a channel) of the transistor. In embodiments, a portion of the semiconductor pattern may be an active area of the transistor, another portion thereof may be a source area or a drain area of the transistor, and another portion thereof may be a connection electrode or a connection signal line.

FIG. 7 illustrates one transistor PXC-T and one light emitting element ED included in the pixel by way of example.

A source area SC, an active area AL, and a drain area DR of the transistor PXC-T may be formed from a semiconductor pattern. The source area SC and the drain area DR may extend from the active area AL in opposite directions on a cross section. FIG. 7 illustrates a portion of a connection signal line SCL formed from the semiconductor pattern. In embodiments, the connection signal line SCL may be connected to the drain area DR of the transistor PXC-T when viewed on a plane (e.g., in a plan view).

A first insulation layer 10 may be on the buffer layer BFL. The first insulation layer 10 may overlap a plurality of pixels in common, and may cover a semiconductor pattern. The first insulation layer 10 may be an inorganic layer and/or an organic layer, and may have a single-layered or multi-layered structure. The first insulation layer 10 may include at least one selected from among aluminum oxide, titanium oxide, silicon oxide, silicon nitride, silicon oxynitride, zirconium oxide, and hafnium oxide. In an embodiment, the first insulation layer 10 may be a single-layered silicon oxide layer. An insulation layer (e.g., an electrical insulation layer) of the circuit layer 120, which will be further described herein, as well as the first insulation layer 10 may be an inorganic layer and/or an organic layer, and may have a single-layered or multi-layered structure. The inorganic layer may include at least one of the above-described materials, but the present disclosure is not limited thereto.

A gate electrode GT of the transistor PXC-T is on the first insulation layer 10. The gate electrode GT may be a portion of a metal pattern. The gate electrode GT overlaps the active area AL. In a process of doping the semiconductor pattern, the gate electrode GT may function as a mask.

A second insulation layer 20 may be on the first insulation layer 10, and may cover the gate electrode GT. The second insulation layer 20 may overlap the pixels in common. The second insulation layer 20 may be an inorganic layer and/or an organic layer, and may have a single-layered or multi-layered structure. The second insulation layer 20 may include at least one selected from among silicon oxide, silicon nitride, and silicon oxynitride. In an embodiment, the second insulation layer 20 may have a multi-layered structure including a silicon oxide layer and a silicon nitride layer.

A third insulation layer 30 may be on the second insulation layer 20. The third insulation layer 30 may have a single-layered or multi-layered structure. For example, the third insulation layer 30 may have a multi-layered structure including a silicon oxide layer and a silicon nitride layer.

A first connection electrode CNE1 may be on the third insulation layer 30. The first connection electrode CNE1 may be electrically connected to the connection signal line SCL through a contact hole CNT-1 that passes through the first, second, and third insulation layers 10, 20, and 30.

A fourth insulation layer 40 may be on the third insulation layer 30. The fourth insulation layer 40 may be a single-layered silicon oxide. A fifth insulation layer 50 may be on the fourth insulation layer 40. The fifth insulation layer 50 may be an organic layer.

A second connection electrode CNE2 may be on the fifth insulation layer 50. The second connection electrode CNE2 may be electrically connected to the first connection electrode CNE1 through a contact hole CNT-2 that passes through the fourth insulation layer 40 and the fifth insulation layer 50.

A sixth insulation layer 60 is on the fifth insulation layer 50 and may cover the second connection electrode CNE2. The sixth insulation layer 60 may be an organic layer.

The lamination relationship of the circuit layers 120 illustrated in FIG. 7 is only an example, and the present disclosure is not particularly limited thereto. For example, at least one selected from among the first to sixth insulation layers 10, 20, 30, 40, 50, and 60 may be omitted, or other insulation layers (e.g., electrical insulation layers) may be further added.

The light emitting element layer 130 may be on the circuit layer 120. The light emitting element layer 130 may include a light emitting element ED. For example, the light emitting element layer 130 may include an organic light emitting material, an inorganic light emitting material, an organic-inorganic light emitting material, a quantum dot, a quantum rod, a micro LED, and/or a nano LED. Hereinafter, it is described as an example that the light emitting element ED is an organic light emitting element, but the present disclosure is not particularly limited thereto.

The light emitting element ED may include a first electrode AE, a light emission layer EL, and a second electrode CE.

The first electrode AE may be on the sixth insulation layer 60. The first electrode AE may be electrically connected to the second connection electrode CNE2 through a contact hole CNT-3 that passes through the sixth insulation layer 60.

A pixel definition layer 70 may be on the sixth insulation layer 60, and may cover a portion of the first electrode AE. An opening 70-OP is defined in the pixel definition layer 70. The opening 70-OP of the pixel definition layer 70 exposes at least a portion of the first electrode AE.

The display area DA (see FIG. 4) may include a first light emission area PXA-R, and a non-light emission area NPXA that is adjacent to the first light emission area PXA-R. The non-light emission area NPXA may be around (e.g., surround) the first light emission area PXA-R. In an embodiment, the first light emission area PXA-R is defined to correspond to a partial area of the first electrode AE, which is exposed by the opening 70-OP. In FIG. 6, the configurations of the display device DD in a cross section corresponding to the first light emission area PXA-R are illustrated by way of example, and a similar description may be applied to a cross section corresponding to the second light emission area PXA-G and the third light emission area PXA-B.

The light emission layer EL may be on the first electrode AE. The light emission layer EL may be provided in an area corresponding to the opening 70-OP. For example, the light emission layer EL may be formed separately from the pixels. When the light emission layer EL is formed separately from the pixels, each of the light emission layers EL may emit light of at least one color of blue, red, and green. However, the present disclosure is not limited thereto, and the light emission layer EL may be connected to the pixels, and may be provided in common. In embodiments, the light emission layer EL may provide blue light or white light.

The second electrode CE may be on the light emission layer EL. The second electrode CE has an integral shape, and may be provided in a plurality of pixels in common.

In embodiments, a hole control layer may be between the first electrode AE and the light emission layer EL. The hole control layer may be provided in common in the light emission area PXA and the non-light emission area NPXA. The hole control layer may include a hole transport layer, and may further include a hole injection layer. An electron control layer may be between the light emission layer EL and the second electrode CE. The electron control layer may include an electron transport layer, and may further include an electron injection layer. The hole control layer and the electron control layer may be formed in common in a plurality of pixels by using an open mask.

An encapsulation layer 140 may be on the light emitting element layer 130. The encapsulation layer 140 may include an inorganic layer, an organic layer, and an inorganic layer that are sequentially laminated, but the layers that constitute the encapsulation layer 140 are not limited thereto.

The inorganic layers may protect the light emitting element layer 130 from moisture and oxygen, and the organic layer may protect the light emitting element layer 130 from foreign substances, such as dust particles. The inorganic layers may include a silicon nitride layer, a silicon oxynitride layer, a silicon oxide layer, a titanium oxide layer, and/or an aluminum oxide layer. The organic layer may include an acrylic organic layer, but the present disclosure is not limited thereto.

The input sensor ISL may include a base layer 150, a first conductive layer 160, a sensing insulation layer 170, a second conductive layer 180, and a cover insulation layer 190.

The base layer 150 may be an inorganic layer including at least one selected from among silicon nitride, silicon oxynitride, and silicon oxide. In embodiments, the base layer 150 may be an organic layer including an epoxy resin, an acrylic resin, and/or an imide-based resin. The base layer 150 may have a single-layered structure or a multi-layered structure, in which layer are laminated along the third direction DR3. According to an embodiment, the base layer 150 may be omitted.

Each of the first conductive layer 160 and the second conductive layer 180 may have a single-layered structure or may have a multi-layered structure, in which layers are laminated along the third direction DR3.

The conductive layer having a single-layered structure may include a metal layer and/or a transparent conductive layer. The metal layer may include molybdenum, silver, titanium, copper, aluminum, and/or alloys thereof. The transparent conductive layer may include a transparent conductive oxide, such as indium tin oxide (ITO), indium zinc oxide (IZO), zinc oxide (ZnO), indium zinc oxide (IZTO), and/or indium zinc tin oxide (IZTO). Furthermore, the transparent conductive layer may include a conductive polymer (e.g., an electrically conductive polymer), such as PEDOT, metal nanowires, graphene, and/or the like.

The multi-layered conductive layer may include metal layers. The metal layers may have a three-layered structure of, for example, titanium/aluminum/titanium. The multi-layered conductive layer may include at least one metal layer and at least one transparent conductive layer.

At least any one selected from among the sensing insulation layer 170 and the cover insulation layer 190 may include an inorganic layer. The inorganic film may include at least one selected from among aluminum oxide, titanium oxide, silicon oxide, silicon nitride, silicon oxynitride, zirconium oxide, and hafnium oxide.

At least any one selected from among the sensing insulation layer 170 and the cover insulation layer 190 may include an organic layer. The organic film may include at least any one selected from among an acrylic resin, a methacrylic resin, a polyisoprene, a vinyl resin, an epoxy resin, a urethane resin, a cellulose resin, a siloxane resin, a polyimide resin, a polyamide resin, and a perylene resin.

The optical path control layer OSL may be on the input sensor ISL. The optical path control layer OSL may be directly on a cover insulation layer 190 of the input sensor ISL.

The optical path control layer OSL includes at least one control pattern CP. The control pattern CP includes an electrode structure EP and a filling pattern FP. The control pattern CP overlaps the non-light emission area NPXA on a plane (e.g., in a plan view). The control pattern CP does not overlap the first light emission area PXA-R on a plane. The control pattern CP may overlap the pixel definition layer 70 on a plane (e.g., in a plan view).

The electrode structure EP includes a plurality of electrodes TE1 and TE2, and a cavity structure is defined in an interior thereof. The cavity structure may be formed by the plurality of electrodes TE1 and TE2 of the electrode structure EP.

The electrode structure EP may include a first transparent electrode TE1 and a second transparent electrode TE2. The first transparent electrode TE1 may be on the input sensor ISL. The first transparent electrode TE1 may be directly on the cover insulation layer 190 of the input sensor ISL. The first transparent electrode TE1 may be under the cavity structure. The second transparent electrode TE2 may be on the first transparent electrode TE1. The second transparent electrode TE2 may be around (e.g., surround) an upper portion and a side portion of the cavity structure. The second transparent electrode TE2 may include upper parts TE2-1a and TE2-2a that are on the cavity structure, and side wall parts TE2-1b and TE2-2b that extend from the upper parts TE2-1a and TE2-2a and are on a side of the cavity structure. The cavity structure may be provided substantially around (e.g., surrounded by) the upper parts TE2-1a and TE2-2a and the side wall parts TE2-1b and TE2-2b.

The first transparent electrode TE1 and the second transparent electrode TE2 may be spaced apart from each other. A portion of the side wall part TE2-b of the second transparent electrode TE2 may be on the input sensor ISL, and a portion of the side wall part TE2-b on the input sensor ISL may be spaced apart from the first transparent electrode TE1.

Each of the first transparent electrode TE1 and the second transparent electrode TE2 may include an optically transparent conductive material. Each of the first transparent electrode TE1 and the second transparent electrode TE2 may include a transparent conductive oxide (TCO). For example, each of the first transparent electrode TE1 and the second transparent electrode TE2 may include indium tin oxide (ITO).

The filling pattern FP is provided in the cavity structure of the electrode structure EP. The filling pattern FP may be between the first transparent electrode TE1 and the second transparent electrode TE2. The filling pattern FP may be on the first transparent electrode TE1, and may be around (e.g., surrounded by) upper parts TE2-1a and TE2-2a and side wall parts TE2-2b of the second transparent electrode TE2, which provide the cavity structure. A portion of the filling pattern FP, which does not overlap the first transparent electrode TE1 on a plane (e.g., in a plan view), may be on the cover insulation layer 190 of the input sensor ISL.

The filling pattern FP includes an electrochromic material. The electrochromic material may be a material, a color of which is reversibly changed when a voltage is applied thereto. The electrochromic material included in the filling pattern FP may be a material that is changed to be colored or optically transparent depending on whether a voltage is applied thereto. The electrochromic material may include at least one selected from among a metal oxide, a metal chloride, and a graphene quantum dot. In embodiments, the electrochromic material may include a conductive polymer (e.g., an electrically conductive polymer) having electrochromic characteristics. The filling pattern FP may include, for example, an oxide of a metal, such as titanium, iron, niobium, molybdenum, and/or tungsten. In embodiments, the filling pattern FP may include a metal chloride, such as potassium chloride. In embodiments, the filling pattern FP may include graphene quantum dots. The filling pattern FP may include a material that is obtained by mixing graphene quantum dots with an electrochromic polymer, such as N,N′-dimethyl-4,4′-bipyridinium.

The filling pattern FP may further include an electrolyte. The electrolyte may be a material that disperses the electrochromic material, and through which a current (e.g., electric current) flows. The filling pattern FP may include a gel-type electrolyte. The gel-type electrolyte may include a polymer having a polar group, a metal salt, and an organic solvent.

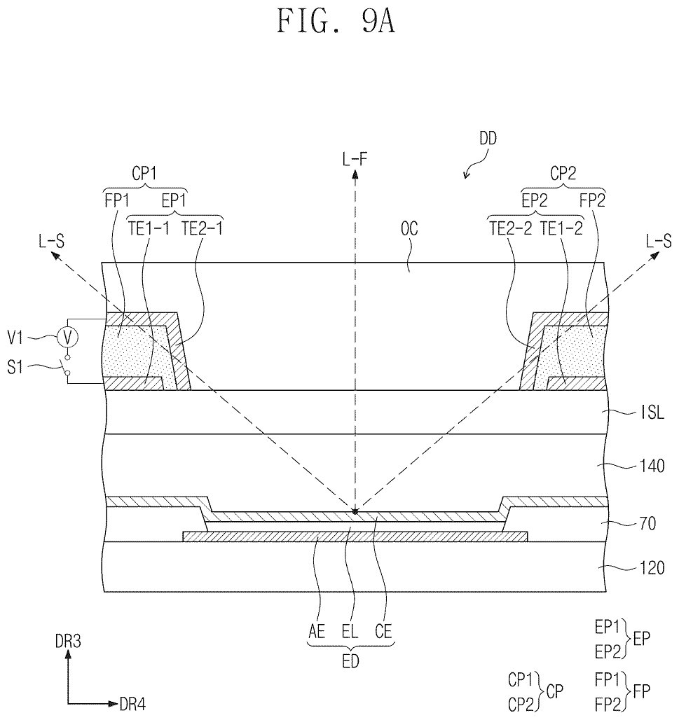

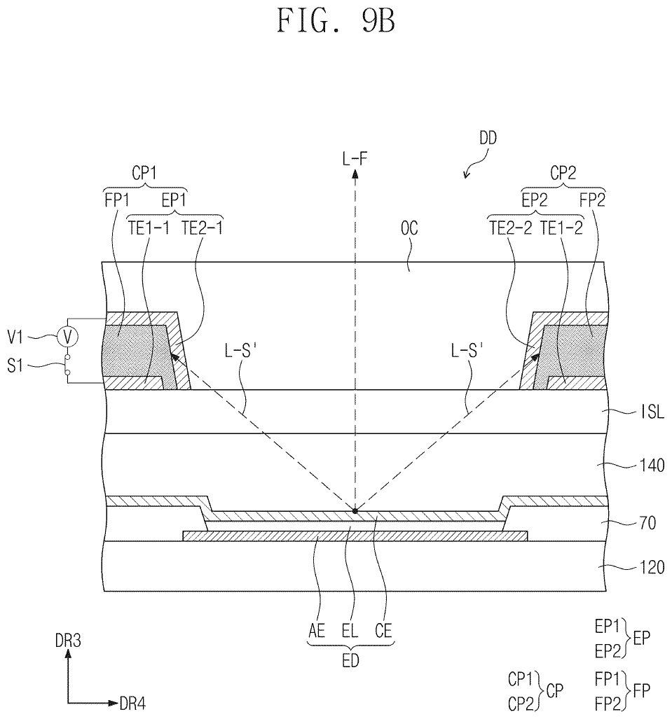

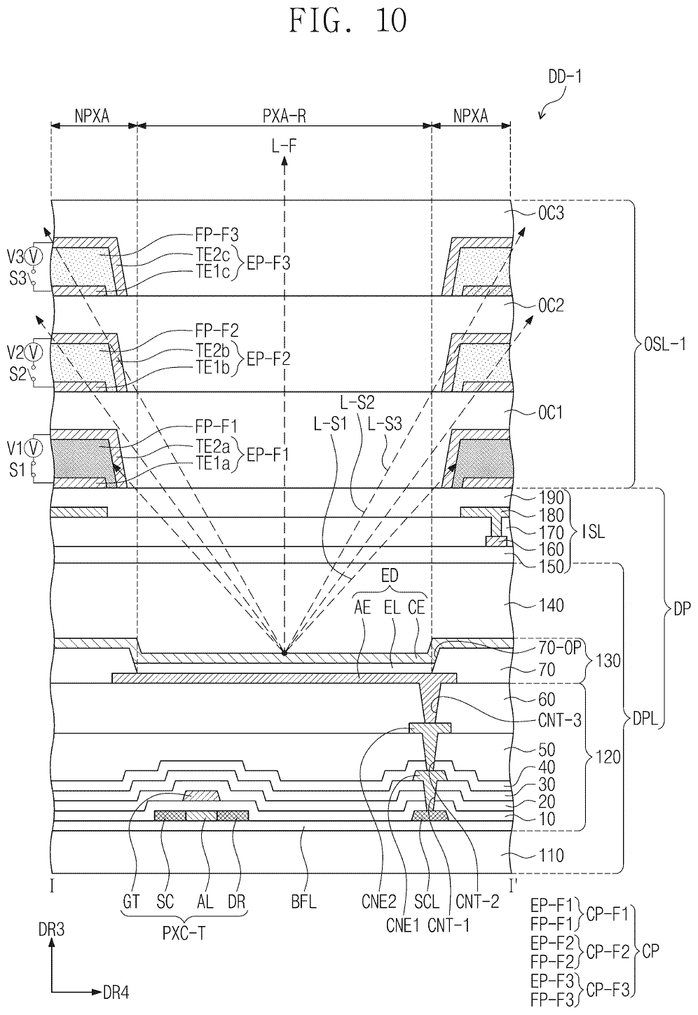

A power source V1 (see FIG. 9A) that may apply a driving voltage may be provided in the electrode structure EP. When a driving voltage is applied to the electrode structure EP, the electrochromic material of the filling pattern FP provided in the cavity structure of the electrode structure EP may be modified to have a color. When a driving voltage is not applied to the electrode structure EP, the electrochromic material of the filling pattern FP may have a light transmittance (e.g., may be transparent). This will be described in more detail with reference to FIGS. 9A and 9B.

The optical path control layer OSL may further include an overcoat layer OC. The overcoat layer OC may be on the control pattern CP. The overcoat layer OC may be on the second transparent electrode TE2 of the control pattern CP. The overcoat layer OC may cover an upper portion of the control pattern CP. The overcoat layer OC may be directly on the second transparent electrode TE2. The overcoat layer OC may be on the control pattern CP, and may protect a configuration provided at a lower portion thereof, and provide a flat upper surface by removing a step (e.g., by reducing a surface step or defect).

The overcoat layer OC may include an optically transparent organic material. Because the overcoat layer OC includes a transparent organic material, light provided from the light emitting element ED may pass through the overcoat layer OC.

The control pattern CP may include a first control pattern CP1 and a second control pattern CP2 that are spaced apart from each other along one direction (e.g., the fourth direction DR4). Each of the first control pattern CP1 and the second control pattern CP2 may be covered by the overcoat layer OC.

Each of the first control pattern CP1 and the second control pattern CP2 may include an electrode structure EP and a filling pattern FP. The first control pattern CP1 may include a first electrode structure EP1 and a first filling pattern FP1, and the second control pattern CP2 may include a second electrode structure EP2 and a second filling pattern FP2. The first electrode structure EP1 includes a (1-1)-th transparent electrode TE1-1 and a (2-1)-th transparent electrode TE2-1, and a first filling pattern FP1 may be disposed in a cavity structure provided between the (1-1)-th transparent electrode TE1-1 and the (2-1)-th transparent electrode TE2-1. The second electrode structure EP2 includes a (1-2)-th transparent electrode TE1-2 and a (2-2)-th transparent electrode TE2-12, and a second filling pattern FP2 may be provided in a cavity structure provided between the (1-2)-th transparent electrode TE1-2 and the (2-2)-th transparent electrode TE2-12. The (2-1)-th transparent electrode TE2-1 may include a first upper part TE2-1a and a first side wall part TE2-1b. The (2-2)-th transparent electrode TE2-2 may include a second upper part TE2-2a and a second side wall part TE2-2b.

Each of the first filling pattern FP1 and the second filling pattern FP2 may include an electrochromic material. Each of the first filling pattern FP1 and the second filling pattern FP2 may include an electrochromic material and an electrolyte.

FIG. 8 is a cross-sectional view of a display device DD according to an embodiment of the present disclosure. FIG. 8 is a cross-sectional view corresponding to cutting line II-II′ illustrated in FIG. 5. In FIG. 8, a cross-section corresponding to 1 adjacent different light emission areas PXA-R, PXA-G, and PXA-B and around (e.g., surrounding) non-light emission areas NPXA is illustrated.

Referring to FIG. 8, the base layer 110 may include a single-layered or multi-layered structure. For example, the base layer 110 may include a first synthetic resin layer, an intermediate layer of a multi-layered or single-layered structure, and a second synthetic resin layer that are sequentially laminated. The intermediate layer may be referred to as a base barrier layer. The intermediate layer may include a silicon oxide (SiOx) layer and an amorphous silicon (a-Si) layer that is on the silicon oxide layer, but the present disclosure is not particularly limited thereto. For example, the intermediate layer may include at least one selected from among a silicon oxide layer, a silicon nitride layer, a silicon oxynitride layer, and an amorphous silicon layer.

Each of the first and second synthetic resin layers may include a polyimide-based resin. Furthermore, each of the first and second synthetic resin layers may include at least one selected from among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the present specification, the “α”-based resin means including a functional group of the “α”.

The circuit layer 120 may be on the base layer 110, and the circuit layer 120 may include a plurality of transistors. Each of the transistors may include a control electrode, an input electrode, and an output electrode. The circuit layer 120 may include a plurality of transistors to drive the light emitting elements ED1, ED2, and ED3 of the light emitting element layer 130.

The light emitting element layer 130 may include a pixel definition layer 70 and first to third light emitting elements ED1, ED2, and ED3. In the pixel definition layer 70, a plurality of pixel openings, in which at least portions of the first to third light emitting elements ED1, ED2, and ED3 are provided, may be defined. The pixel 1 definition layer 70 may include an organic light shielding material including a black pigment and/or a black dye, and/or an inorganic light shielding material.

The display panel DP may be divided into a non-light emission area NPXA and light emission areas PXA-R, PXA-G, and PXA-B. The light emission areas PXA-R, PXA-G, and PXA-B may be areas, through which lights generated by the first to third light emitting elements ED1, ED2, and ED3 are emitted, respectively. The light emission areas PXA-R, PXA-G, and PXA-B may be spaced apart from each other on a plane (e.g., in a plan view).

The light emission areas PXA-R, PXA-G, and PXA-B may be areas that are divided by the pixel definition layer 70. The non-light emission areas NPXA may be areas between adjacent light emission areas PXA-R, PXA-G, and PXA-B, and may be areas corresponding to the pixel definition layer 70. In embodiments, each of the light emission areas PXA-R, PXA-G, and PXA-B may correspond to a pixel. The pixel definition layer 70 may divide the first to third light emitting elements ED1, ED2, and ED3. The light emission layers EL1, EL2, and EL3 of the first to third light emitting elements ED1, ED2, and ED3 may be provided in a pixel opening OH defined in the pixel definition layer 70.

The light emission areas PXA-R, PXA-G, and PXA-B may be divided into a plurality of groups depending on colors of the lights generated by the first to third light emitting elements ED1, ED2, and ED3. In the display panel DP of an embodiment illustrated in FIG. 8, three light emission areas PXA-R, PXA-G, and PXA-B that emit red light, green light, and blue light are illustrated by way of example. For example, the display device DD according to an embodiment may include a first light emission area PXA-R, a second light emission area PXA-G, and a third light emission area PXA-B, which are distinguished from each other.

The first to third light emitting elements ED1, ED2, and ED3 may be spaced apart from each other in one direction (e.g., the second direction DR2 or the fourth direction DR4) that is perpendicular (e.g., substantially perpendicular) to the thickness direction DR3. The first to third light emitting elements ED1, ED2, and ED3 may emit light of different wavelength areas (e.g., different wavelength ranges). For example, the first light emitting element ED1 may emit red light, the second light emitting element ED2 may emit green light, and the third light emitting element ED3 may emit blue light. The first light emission area PXA-R, the second light emission area PXA-G, and the third light emission area PXA-B may correspond to the first light emitting element ED1, the second light emitting element ED2, and the third light emitting element ED3, respectively. However, an embodiment is not limited thereto, and the first to third light emitting elements ED1, ED2, and ED3 may emit light of the same wavelength area (e.g., wavelength range), or at least one selected from among the first to third light emitting elements ED1, ED2, and ED3 may emit light of different wavelength areas (e.g., wavelength ranges). For example, all of the first to third light emitting elements ED1, ED2, and ED3 may emit blue light.

Each of the light emitting elements ED1, ED2, and ED3 may include a first electrode AE, a second electrode CE on the first electrode AE, and light emission layers EL1, EL2, and EL3 that are between the first electrode AE and the second electrode CE. The first electrode AE may be exposed in a pixel opening OH of the pixel definition layer 70.

Furthermore, each of the light emitting elements ED1, ED2, and ED3 may further include a hole control layer and an electronic control layer. The hole control layer may be between the first electrode AE and the light emission layers EL1, EL2, and EL3. The electronic control layer may be between the light emission layers EL1, EL2, and EL3 and the second electrode CE. In embodiments, the hole control layer and the electronic control layer may be formed as a common layer to overlap all of the first light emission area PXA-R, the second light emission area PXA-G, and the third light emission area PXA-B by using an open mask.

The first electrode AE may be an anode. However, an embodiment is not limited thereto. Furthermore, the first electrode AE may be a pixel electrode. The first electrode AE may be a transmissive electrode, a semi-transmissive electrode, or a reflective electrode.

When the first electrode AE is a transmissive electrode, the first electrode AE may include a transparent metal oxide, for example, indium tin oxide (ITO), indium zinc oxide (IZO), zinc oxide (ZnO), indium tin oxide (ITZO), and/or the like. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a lamination structure of LiF and Ca), LiF/Al (a lamination structure of LiF and Al), Mo, Ti, W, or a compound or mixture thereof (for example, a mixture of Ag and Mg). In embodiments, the first electrode AE may have a plurality of layer structures including a reflective film formed of the above materials and/or a transparent conductive film formed of a semi-transmissive film, such as indium tin oxide (ITO), indium zinc oxide (IZO), zinc oxide (ZO), indium tin zinc oxide (ITZO), and/or the like. For example, the first electrode AE may have a three-layered structure of ITO/Ag/ITO, but the present disclosure is not limited thereto. Furthermore, the first electrode AE may include the above-described metal materials, a combination of two or more metal materials selected from the above-described metal materials, an oxide of the above-described metal materials, and/or the like, and an embodiment is not limited thereto.

The light emission layers EL1, EL2, and EL3 may have a single layer made of a single material, a single layer made of a plurality of different materials, or a multi-layered structure having a plurality of layers made of a plurality of different materials. The light emission layers EL1, EL2, and EL3 may include an anthracene derivative, a pyrene derivative, a fluorantene derivative, a chrycene derivative, a dihydrobenzanthracene derivative, and/or a triphenylene derivative.

For example, the light emission layers EL1, EL2, and EL3 may include one host and one dopant. In embodiments, the light emission layers EL1, EL2, and EL3 may include two or more hosts and dopants.

The light emission layer EL3 of the third light emitting element ED3, which emits blue light, may emit thermally activated delayed fluorescence (TADF) and/or phosphorescent light. The light emission layer EL3 of the third light emitting element ED3 may include a thermally activated delayed fluorescence material and/or a phosphorescent material. The third light emitting element ED3 including a thermally activated delayed fluorescence material and/or a phosphorescent material may exhibit an excellent luminous efficiency.

The light emission layers EL1, EL2, and EL3 may include any suitable dopant materials, and may include styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl) naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and/or its derivatives (e.g., 2,5,8,11-Tetra-t-butylperylene (TBP)), and/or pyrene and/or its derivatives (e.g., 1,1-dipyrene, 1,4-dipyrenylbenzene, 1,4-Bis(N, N-diphenylamino)pyrene).

The light emission layers EL1, EL2, and EL3 may include any suitable phosphorescent dopant material. For example, the phosphorescent dopant may be a metal complex containing iridium (Ir), platinum (Pt), osmium (Os), gold (Au), titanium (Ti), zirconium (Zr), hafnium (Hf), europium (Eu), terbium (Tb), or thulium (Tm). In embodiments, Flrpic (iridium(III) bis(4,6-difluorophenylpyridato-N,C2′)picolinate, Flr6 (Bis(2,4-difluorophenylpyridinato)-tetrakis(1-pyrazolyl)borate iridium(III)), and/or platinum octaethyl pyridine (PtOEP) may be used as the phosphorescent dopant. However, an embodiment is not limited thereto.

The second electrode CE may be a common electrode. The second electrode CE may be a cathode, but an embodiment is not limited thereto. The second electrode CE may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, a mixture thereof, and/or an oxide thereof.

In embodiments, the light emitting elements ED1, ED2, and ED3 may further include a capping layer that is on the second electrode CE. The capping layer may be an organic layer and/or an inorganic layer. For example, when the capping layer includes an inorganic material, the inorganic material may include an alkali metal compound, such as, for example, LiF, an alkaline earth metal compound, such as MgF2, SiON, SiNₓ, SiO_{y}, and/or the like. For example, when the capping layer includes an organic material, the organic material may include α-NPD, NPB, TPD, m-MTDATA, Alq3, CuPc, TPD15 (N4,N4,N4′,N4′,N4′-tetra (biphenyl-4′-diamine), TCTA (4,4′,4′-tris(carbazol-9-yl)triphenylamine), and/or the like, and/or may include an epoxy resin and/or an acrylate, such as methacrylate.

An encapsulation layer 140 may be on the light emitting element layer 130. The encapsulation layer 140 may include an inorganic layer, an organic layer, and an inorganic layer sequentially laminated.

The input sensor ISL may be on the encapsulation layer 140. The input sensor ISL may be directly on the encapsulation layer 140.

The optical path control layer OSL may be on the input sensor ISL. The optical path control layer OSL includes at least one control pattern CP. The control pattern CP is on the input sensor ISL. The control pattern CP includes an electrode structure EP and a filling pattern FP. The electrode structure EP includes a cavity structure that is formed by a plurality of electrodes TE1 and TE2, and the filling pattern FP is provided in the cavity. The filling pattern FP includes an electrochromic material. The filling pattern FP may further include a gel-type electrolyte that disperses the electrochromic material, and through which a current (e.g., electric current) flows.

The control pattern CP may be provided in correspondence to the non-light emission area NPXA. The control pattern CP may overlap the pixel definition layer 70 on a plane (e.g., in a plan view). As illustrated in FIG. 8, the control pattern CP may overlap a portion of the non-light emission area NPXA, and may not overlap the light emission areas PXA-R, PXA-G, and PXA-B. For example, the control pattern CP may not overlap each of the light emitting elements ED1, ED2, and ED3 on a plane (e.g., in a plan view). In embodiments, the control pattern CP may overlap the entire non-light emission area NPXA.

The optical path control layer OSL may further include an overcoat layer OC. A portion of the overcoat layer OC may be between the adjacent control patterns CP to fill a space that is defined between the spaced control patterns CP. The remaining portion of the overcoat layer OC may be on the control pattern CP and may cover an upper portion of the control pattern CP.

FIG. 9A is a cross-sectional view illustrating a display device according to an embodiment of the present disclosure when it is operated in a first mode. FIG. 9B is a cross-sectional view illustrating a display device according to an embodiment of the present disclosure when it is operated in a second mode. In FIGS. 9A and 9B, in cross sections corresponding to a light emission area and a non-light emission area that is adjacent thereto, travel directions of a front surface light and a side surface light in the first mode and the second mode are illustrated.

Referring to FIGS. 7 and 9A, the control pattern CP may include a first control pattern CP1 and a second control pattern CP2 that are spaced apart from each other along one direction (e.g., the fourth direction DR4). A portion of the overcoat layer OC may be between the first control pattern CP1 and the second control pattern CP2, and the remaining portion of the overcoat layer OC may cover the first control pattern CP1 and the second control pattern CP2 on the first control pattern CP1 and the second control pattern CP2.

Each of the first control pattern CP1 and the second control pattern CP2 may include an electrode structure EP and a filling pattern FP. The first control pattern CP1 may include a first electrode structure EP1 and a first filling pattern FP1, and the second control pattern CP2 may include a second electrode structure EP2 and a second filling pattern FP2. The first electrode structure EP1 includes a (1-1)-th transparent electrode TE1-1 and a (2-1)-th transparent electrode TE2-1, and a first filling pattern FP1 may be provided in a cavity structure provided between the (1-1)-th transparent electrode TE1-1 and the (2-1)-th transparent electrode TE2-1. The second electrode structure EP2 includes a (1-2)-th transparent electrode TE1-2 and a (2-2)-th transparent electrode TE2-12, and a second filling pattern FP2 may be provided in a cavity structure provided between the (1-2)-th transparent electrode TE1-2 and the (2-2)-th transparent electrode TE2-12. Each of the first filling pattern FP1 and the second filling pattern FP2 may include an electrochromic material. Each of the first filling pattern FP1 and the second filling pattern FP2 may include an electrochromic material and an electrolyte.

A first power source V1 may be provided to the electrode structure EP. In FIG. 9A, only the first power source V1 connected to the (1-1)-th transparent electrode TE1-1 and the (2-1)-th transparent electrode TE2-1 of the first electrode structure EP1 is illustrated, but the first power source V1 may also be provided to the (1-2)-th transparent electrode TE1-2 and the (2-2)-th transparent electrode TE2-12 of the second electrode structure EP2.

Referring to FIGS. 7 and 9A, when the display device DD according to an embodiment is operated in the first mode, the electrode structure EP and the first power source V1 are not electrically connected to each other as a first switch S1 is opened, and a separate voltage is not applied to the electrode structure EP. Accordingly, an open circuit, to which the first power source V1 is not provided, may be formed in the electrode structure EP. In the first mode, an electric field may not be generated between the first transparent electrode TE1 and the second transparent electrodes TE2 of the electrode structure EP. Because a separate electric field is not generated between the first and second transparent electrodes TE1 and TE2 in the first mode, the electrochromic material may not be modified, and may have a light transmittance (e.g., may be transparent).

In the first mode, in which no separate voltage is applied to the electrode structure EP, light that travels to the first control pattern CP1 and the second control pattern CP2 may pass through the first control pattern CP1 and the second control pattern CP2, respectively. For example, a side surface light L-S that travels from the light emitting element ED to the first control pattern CP1 and the second control pattern CP2 may pass through the control pattern CP and may travel to an upper portion of the display device DD. When the display device DD according to an embodiment is operated in the first mode, both the front surface light L-F and the side surface light L-S generated from the light emitting element ED may travel to an upper portion of the display device DD. Accordingly, in the first mode, the display device DD may be operated to have a wide viewing angle.

Referring to FIGS. 7 and 9B, when the display device DD according to an embodiment is operated in the second mode, the electrode structure EP and the first power source V1 may be electrically connected to each other according to a closed state of the first switch S1b so that a closed circuit may be formed. In the second mode, an electric field may be generated between the first transparent electrode TE1 and the second transparent electrodes TE2 of the electrode structure EP. In the second mode, an electric field may be formed between the first transparent electrode TE1 and the second transparent electrode TE2, and thus, the electrochromic material of the filling pattern FP may be modified to have a color.

In the second mode, in which a first power source V1 is applied to the electrode structure EP, light that travels to the first control pattern CP1 and the second control pattern CP2 may not pass through the first control pattern CP1 and the second control pattern CP2. For example, a side surface light L-S that travels from the light emitting element ED to the first control pattern CP1 and the second control pattern CP2 may not pass through the control pattern CP and may not travel to an upper portion of the display device DD. The side surface light L-S′ that travels to each of the first control pattern CP1 and the second control pattern CP2 may not pass through the control pattern CP because it is absorbed or reflected by the electrochromic material modified to have a color. When the display device DD according to an embodiment is operated in the second mode, the front surface light L-F generated from the light emitting element ED may travel to an upper portion of the display device DD, but the side surface light L-S′ may be scattered by each of the first control pattern CP1 and the second control pattern CP2 and may not travel to the upper portion of the display device DD. Accordingly, in the second mode, the display device DD may be operated to have a narrow viewing angle.

The display device DD according to an embodiment of the present disclosure may include a control pattern CP that overlaps at least the non-light emission area NPXA and includes a filling pattern FP including the electrochromic material, and may selectively be operated in any one of the first mode, in which a screen is displayed at a wide viewing angle, or a second mode, in which a screen is displayed at a narrow viewing angle. Furthermore, the display device according to an embodiment may provide an image while not deteriorating or reducing a resolution even through the viewing angle is switched to a different mode.

In another display device, to selectively be operated in any one of the first mode to display a screen at the first viewing angle or the second mode to display a screen at the second viewing angle that is narrower than the first viewing angle, a light shielding pattern structure that overlaps is formed adjacent to some pixels (or light emitting elements) is formed. In such a display device, a side luminance is lowered even in the first mode due to the light shielding pattern, and in each mode, only some pixels (or light emitting elements) are operated so that a problem that the resolution of the display device is reduced occurs. The display device DD according to an embodiment provides a control pattern CP including a filling pattern FP including an electrochromic material without a division structure of pixels (or light emitting elements), so that the side surface light may pass through the control pattern CP in the first mode to display a screen at a wide viewing angle, and the side surface light may not pass through the control pattern CP and may be scattered in the second mode to display a screen at a narrow viewing angle. Accordingly, it is possible to provide a display device, in which a viewing angle is selectively operated in different modes without lowering the side luminance and the resolution.

FIG. 10 is a cross-sectional view of a display device according to an embodiment of the present disclosure. FIG. 10 illustrates a display device DD-1 according to an embodiment and the display device DD-1 according to an embodiment illustrated in FIGS. 7 to 9B.

Referring to FIG. 10, in an optical path control layer OSL-1 included in the display device DD-1 according to an embodiment, the control pattern CP may be provided in a plurality of layers. The control pattern CP may include a first layer control pattern CP-F1, a second layer control pattern CP-F2, and a third layer control pattern CP-F3. The first layer control pattern CP-F1 may be on the input sensor ISL. The second layer control pattern CP-F2 may be on the first layer control pattern CP-F1. The third layer control pattern CP-F3 may be on the second layer control pattern CP-F2.

Each of the first layer control pattern CP-F1, the second layer control pattern CP-F2, and the third layer control pattern CP-F3 may be provided in correspondence to the non-light emission area NPXA. Each of the first layer control pattern CP-F1, the second layer control pattern CP-F2, and the third layer control pattern CP-F3 may overlap the pixel definition layer 70 on a plane (e.g., in a plan view). Each of the first layer control pattern CP-F1, the second layer control pattern CP-F2, and the third layer control pattern CP-F3 may overlap a portion of the non-light emission area NPXA, and may not overlap the light emission areas PXA-R, PXA-G, and PXA-B. The first layer control pattern CP-F1, the second layer control pattern CP-F2, and the third layer control pattern CP-F3 may be provided in parallel (e.g., substantially in parallel) to completely overlap each other on the plane.

The first layer control pattern CP-F1 may include a first layer electrode structure EP-F1, in which a first cavity is defined, and a first layer filling pattern FP-F1 that is filled in the first cavity. The second layer control pattern CP-F2 may include a second layer electrode structure EP-F2, in which a second cavity is defined, and a second layer filling pattern FP-F2 that is filled in the second cavity. The third layer control pattern CP-F3 may include a third layer electrode structure EP-F3, in which a third cavity is defined, and a third layer filling pattern FP-F3 that is filled in the third cavity. Each of the first layer filling pattern FP-F1, the second layer filling pattern FP-F2, and the third layer filling pattern FP-F3 may include the electrochromic material described above. Each of the first layer filling pattern FP-F1, the second layer filling pattern FP-F2, and the third layer filling pattern FP-F3 may further include a gel-type electrolyte to disperse the electrochromic material, and through which a current (e.g., electric current) flows.

Each of the first layer electrode structure EP-F1, the second layer electrode structure EP-F2, and the third layer electrode structure EP-F3 may include a plurality of electrodes that defines a cavity structure. The first layer electrode structure EP-F1 may include a 1a-th transparent electrode TE1a and a 2a-th transparent electrode TE2a that is on the 1a-th transparent electrode TE1a. The second layer electrode structure EP-F2 may include a 1b-th transparent electrode TE1b and a 2b-transparent electrode TE2b that is on the 1b-th transparent electrode TE1b. The third layer electrode structure EP-F3 may include a 1c-th transparent electrode TE1c and a 2c-th transparent electrode TE2c that is on the 1c-th transparent electrode TE1c. The first layer filling pattern FP-F1 may be between the 1a-th transparent electrode TE1a and the 2a-th transparent electrode TE2a, the second layer filling pattern FP-F2 may be between the 1b-th transparent electrode TE1b and the 2b-th transparent electrode TE2b, and the third layer filling pattern FP-F3 may be between the 1c-th transparent electrode TE1c and the 2c-th transparent electrode TE2c.

Separate power sources may be provided in the first layer electrode structure EP-F1, the second layer electrode structure EP-F2, and the third layer electrode structure EP-F3, respectively. A first power source V1 may be provided in the first layer electrode structure EP-F1, a second power source V2 may be provided in the second layer electrode structure EP-F2, and a third power source V3 may be provided in the third layer electrode structure EP-F3. The first layer electrode structure EP-F1 and the first power source V1 may constitute a first circuit, the second layer electrode structure EP-F2 and the second power source V2 may constitute a second circuit, and the third layer electrode structure EP-F3 and the third power source V3 may constitute a first circuit. The first circuit, the second circuit, and the third circuit may be distinguished from each other, and may be driven separately.

The optical path control layer OSL-1 may further include overcoat layers OC1, OC2, and OC3. The overcoat layers OC1, OC2, and OC3 may cover each of the control patterns CP provided as a plurality of layers. The overcoat layers OC1, OC2, and OC3 may include a first overcoat layer OC1 that covers the first layer control pattern CP-F1, a second overcoat layer OC2 that covers the second layer control pattern CP-F2, and a third overcoat layer OC3 that covers the third layer control pattern CP-F3. The second layer control pattern CP-F2 may be directly on the first overcoat layer OC1, and the third layer control pattern CP-F3 may be directly on the second overcoat layer OC2. The first layer control pattern CP-F1 may be directly on the cover insulation layer 190 of the input sensor ISL described above.

The display device DD-1 according to an embodiment illustrated in FIG. 10 may be operated in a first mode, a second mode, a third mode, a fourth mode, and/or the like as the first circuit, the second circuit, and the third circuit described above are distinguished and are driven while being divided. FIG. 10 illustrates a cross section when the display device DD-1 is operated in the second mode.

When the display device DD-1 according to an embodiment is operated in the first mode, all of the first switch S1, the second switch S2, and the third switch S3 may be in an open state. Accordingly, the first layer electrode structure EP-F1 and the first power source V1 may not be electrically connected to each other so that the first circuit may be in an open circuit state, and the second layer electrode structure EP-F2 and the second power source V2 may not be electrically connected to each other so that the second circuit may be in an open circuit state, and the third layer electrode structure EP-F3 and the third power source V3 may not be electrically connected each other so that the third circuit may be in an open circuit state. In the first mode, a separate electric field may not be generated between the (1-a)-th transparent electrode TE1-a and the (2-a)-th transparent electrode TE2-a of the first layer electrode structure EP-F1, between the (1-b)-th transparent electrode TE1-b and the (2-b)-th transparent electrode TE2-b of the second layer electrode structure EP-F2, and between the (1-c)-th transparent electrode TE1-c and the (2-c)-th transparent electrode TE2-c of the third layer electrode structure EP-F3. In the first mode, because an electric field is not formed in each of the first layer electrode structure EP-F1, the second layer electrode structure EP-F2, and the third layer electrode structure EP-F3, an electrochromic material included in each of the first layer filling pattern FP-F1, the second layer filling pattern FP-F2, and the third layer filling pattern FP-F3 may be maintained in an optically transparent state.

In a state in which the electrochromic material included in each of the first layer filling pattern FP-F1, the second layer filling pattern FP-F2, and the third layer filling pattern FP-F3 is optically transparent, the lights that travel to the first layer control pattern CP-F1, the second layer control pattern CP-F2, and the third layer control pattern CP-F3 may pass through the first layer control pattern CP-F1, the second layer control pattern CP-F2, and the third layer control pattern CP-F3, respectively. For example, the third side surface light L-S3 that travels from the light emitting element ED to the first layer control pattern CP-F1, the second side surface light L-S2 that travels from the light emitting element ED to the second layer filling pattern FP-F2, and the third side surface light L-S3 that travels from the light emitting element ED to the third layer filling pattern FP-F3 may pass through the control patterns CP provided to the plurality of layers, respectively, and may travel to an upper portion of the display device DD-1. When the display device DD-1 according to an embodiment is operated in the first mode, all of the front surface light L-F, and the first side surface light L-S1, the second side surface light L-S2, and the third side surface light L-S3 that are generated from the light emitting element ED may travel to an upper portion of the display device DD-1. Accordingly, in the first mode, the display device DD-1 may be operated to have the widest viewing angle.

When the display device DD-1 according to an embodiment is operated in the second mode, the first switch S1 may be in a closed state, and the second switch S2 and the third switch S3 may be in an open state. Accordingly, the first layer electrode structure EP-F1 and the first power source V1 are electrically connected to each other so that the first circuit is in a closed circuit state, and the second circuit constituted by the second layer electrode structure EP-F2 and the second power source V2 and the third circuit constituted by the third layer electrode structure EP-F3 and the third power source V3 may be maintain in an open circuit state, respectively. In the second mode, an electric field may be generated between the (1-a)-th transparent electrode TE1-a and the (2-a)-th transparent electrode TE2-a of the first layer electrode structure EP-F1, and a separate electric field may not be generated between the (1-b)-th transparent electrode TE1-b and the (2-b)-th transparent electrode TE2-b of the second layer electrode structure EP-F2, and between the (1-c)-th transparent electrode TE1-c and the (2-c)-th transparent electrode TE2-c of the third layer electrode structure EP-F3. In the second mode, an electric field is formed only in the first layer electrode structure EP-F1, and thus the electrochromic material of the first layer filling pattern FP-F1 provided in the first cavity of the first layer electrode structure EP-F1 may be modified to have a color. An electric field is not formed in each of the second layer electrode structure EP-F2 and the third layer electrode structure EP-F3, and thus an electrochromic material included in each of the second layer filling pattern FP-F2 and the third layer filling pattern FP-F3 may be maintained in an optically transparent state.

In a state in which the electrochromic material of the first layer filling pattern FP-F1 is modified to have a color, the first side surface light L-S1 that travels to the first layer control pattern CP-F1 may not pass through the first layer control pattern CP-F1 because it is absorbed or reflected by the electrochromic material of a color. The second side surface light L-S2 that travels from the light emitting element ED to the second layer filling pattern FP-F2 and the third side surface light L-S3 that travels from the light emitting element ED to the third layer filling pattern FP-F3 may pass through the control patterns CP, respectively, and may travel to an upper portion of the display device DD-1. When the display device DD-1 according to an embodiment is operated in the second mode, the front surface light L-F, the second side surface light L-S2, and the third side surface light L-S3 generated from the light emitting element ED may travel to an upper portion of the display device DD-1, and the first side surface light L-S1 having the widest viewing angle may not travel to the upper portion of the display device DD-1. Accordingly, in the second mode, the display device DD-1 may be operated to have a narrower viewing angle compared to the first mode.

When the display device DD-1 according to an embodiment is operated in a third mode, both of the first switch S1 and the second switch S2 may be in a closed state, and the third switch S3 may be in an open state. Accordingly, the first circuit constituted by the first layer electrode structure EP-F1 and the first power source V1, and the second circuit constituted by the second layer electrode structure EP-F2 and the second power source V2 be in a closed circuit state, and the third circuit constituted by the third layer electrode structure EP-F3 and the third power source V3 may be maintained in an open circuit state. In the third mode, an electric field may be generated between the (1-a)-th transparent electrode TE1-a and the (2-a)-th transparent electrode TE2-a of the first layer electrode structure EP-F1 and between the (1-b)-th transparent electrode TE1-b and the (2-b)-th transparent electrode TE2-b of the second layer electrode structure EP-F2, and a separate electric field may not be generated between the (1-c)-th transparent electrode TE1-c and the (2-c)-th transparent electrode TE2-c of the third layer electrode structure EP-F3. In the third mode, an electric field may be formed in the first layer electrode structure EP-F1 and the second layer electrode structure EP-F2 so that the electrochromic material of each of the first layer filling pattern FP-F1 provided in the first cavity of the first layer electrode structure EP-F1 and the second layer filling pattern FP-F2 provided in the second cavity of the second layer electrode structure EP-F2 may be modified to have a color. An electric field is not formed in the third layer electrode structure EP-F3, and thus an electrochromic material included in the third layer filling pattern FP-F3 may be maintained in an optically transparent state.

In a state in which the electrochromic material of each of the first layer filling pattern FP-F1 and the second layer filling pattern FP-F2 is modified to have a color, each of the first side surface light L-S1 that travels to the first layer control pattern CP-F1 and the second side surface light L-S2 that travels to the second layer control pattern CP-F2 may be absorbed or reflected by the electrochromic material of the color, and thus may not pass through the first layer control pattern CP-F1 and the second layer control pattern CP-F2. A third side surface light L-S3 that travels from the light emitting element ED to the third layer filling pattern FP-F3 may pass through the control patterns CPs, and travel to an upper portion of the display device DD-1. When the display device DD-1 according to an embodiment is operated in the third mode, the front surface light L-F and the third side surface light L-S3 generated from the light emitting element ED may travel to an upper portion of the display device DD-1, and the first side surface light L-S1 and the second side surface light L-S2 having a wide viewing angle may not travel to the upper portion of the display device DD-1. Accordingly, in the third mode, the display device DD-1 may be operated to have a narrower viewing angle than in the first mode and the second mode.

When the display device DD-1 according to an embodiment is operated in a fourth mode, all of the first to third switches S1 to S3 may be in a closed state. Accordingly, the first circuit constituted by the first layer electrode structure EP-F1 and the first power source V1, the second circuit constituted by the second layer electrode structure EP-F2 and the second power source V2, and the third circuit constituted by the third layer electrode structure EP-F3 and the third power source V3 may be in a closed circuit state, respectively. In the fourth mode, an electric field may be generated between the (1-a)-th transparent electrode TE1-a and the (2-a)-th transparent electrode TE2-a of the first layer electrode structure EP-F1, between the (1-b)-th transparent electrode TE1-b and the (2-b)-th transparent electrode TE2-b of the second layer electrode structure EP-F2, and between the (1-c)-th transparent electrode TE1-c and the (2-c)-th transparent electrode TE2-c of the third layer electrode structure EP-F3. In the third mode, an electric field is formed in each of the first layer electrode structure EP-F1, the second layer electrode structure EP-F2, and the third layer electrode structure EP-F3, so that the electrochromic material of the first layer filling pattern FP-F1 provided in the first cavity of the first layer electrode structure EP-F1, the second layer filling pattern FP-F2 provided in the second cavity of the second layer electrode structure EP-F2, and the third layer filling pattern FP-F3 provided in the third cavity of the third layer electrode structure EP-F3 may be modified to have a color.

In a state in which the electrochromic material of each of the first to third layer filling patterns FP-F1 to FP-F3 is modified to have a color, each of the first side surface light L-S1 that travels to the first layer control pattern CP-F1, the second side surface light L-S2 that travels to the second layer control pattern CP-F2, and the third side surface light L-S3 that travels to the third layer filling pattern FP-F3 may be absorbed or reflected by the electrochromic material of the color, and thus may not pass through the first to third layer control patterns CP-F1 to CP-F3. When the display device DD-1 according to an embodiment is operated in the fourth mode, the front surface light L-F generated from the light emitting element ED may travel to the upper portion of the display device DD, but each of the first to third side surface light L-S1 to L-S3 may not travel to the upper portion of the display device DD-1. Accordingly, in the fourth mode, the display device DD-1 may be operated to have a narrower viewing angle than in the first mode, the second mode, and the third mode.

The display device DD-1 according to an embodiment includes control patterns CP-F1, CP-F2, and CP-F3, in which the optical path control layer OSL-1 is provided in three layers, and has first to third circuits that are separately driven, and thus may be selectively operated in four or more display modes having different viewing angles.

FIG. 10 illustrates that the optical path control layer OSL-1 of the display device DD-1 according to an embodiment has three circuits that are separately driven while including the control patterns CP-F1, CP-F2, and CP-F3 provided in three layers by way of example, but the present disclosure is not limited thereto, and the optical path control layer OSL-1 of the display device DD-1 may have two circuits while including the control pattern CP provided in two layers, or may have four or more circuits while including the control pattern CP provided in four or more layers.

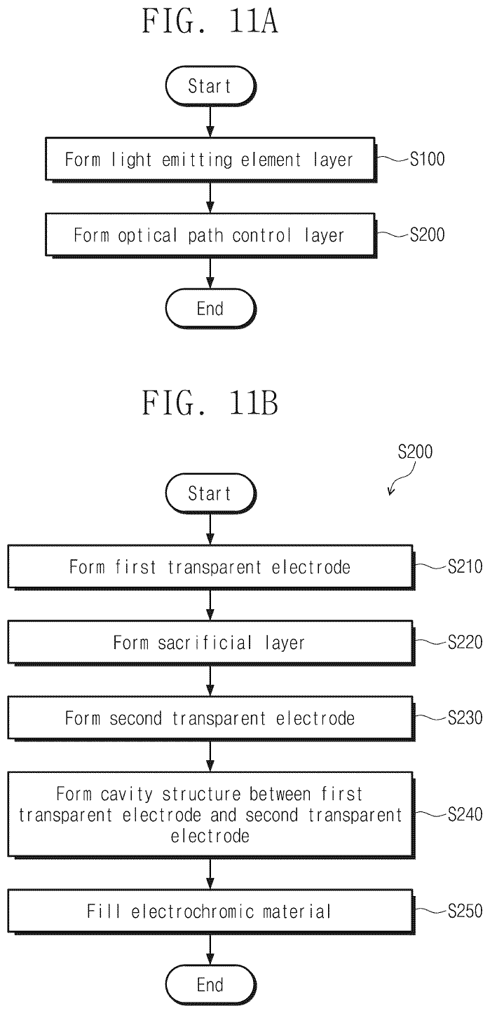

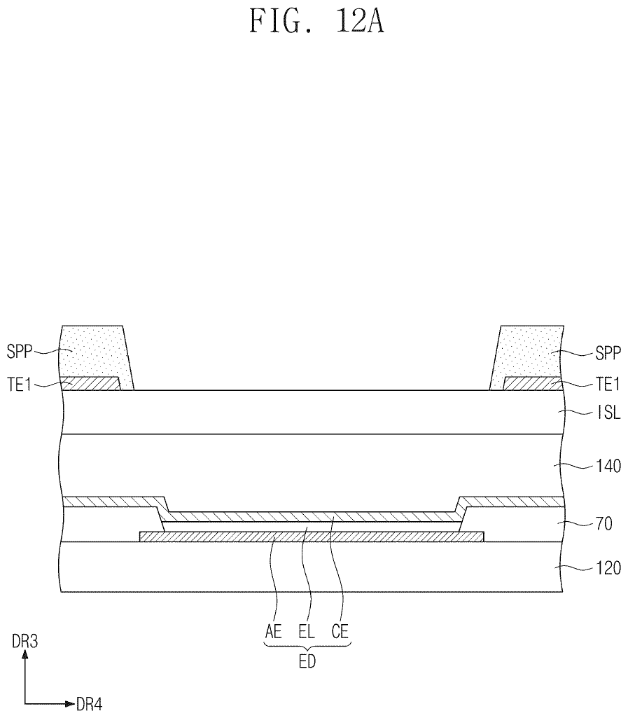

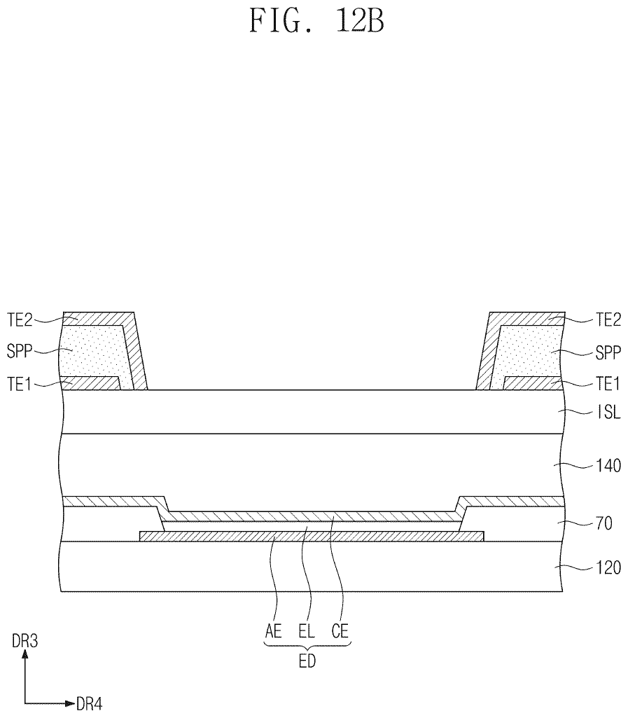

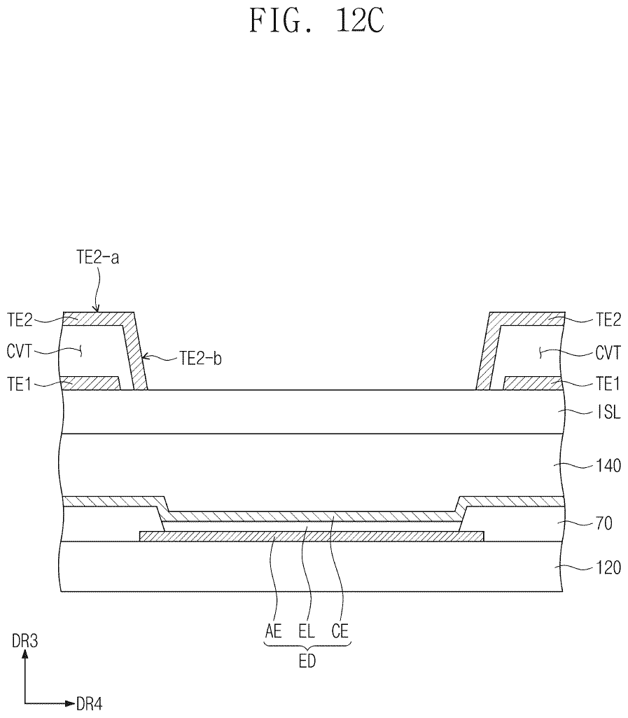

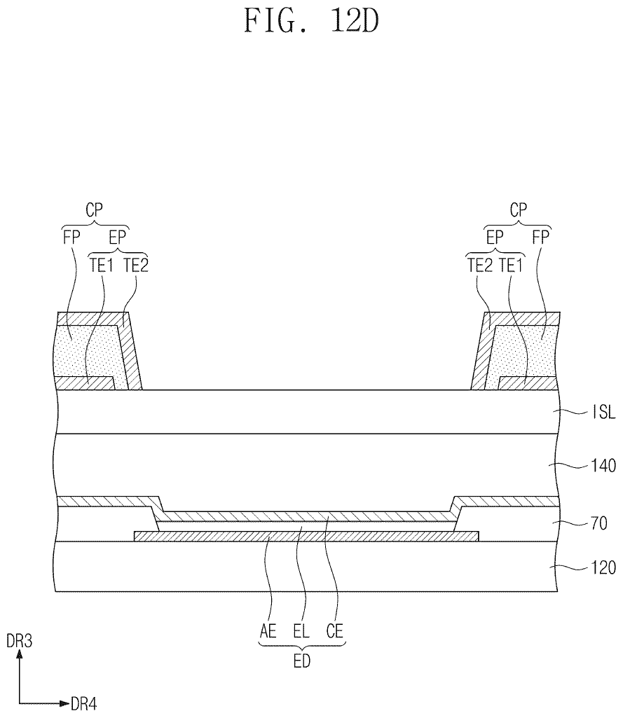

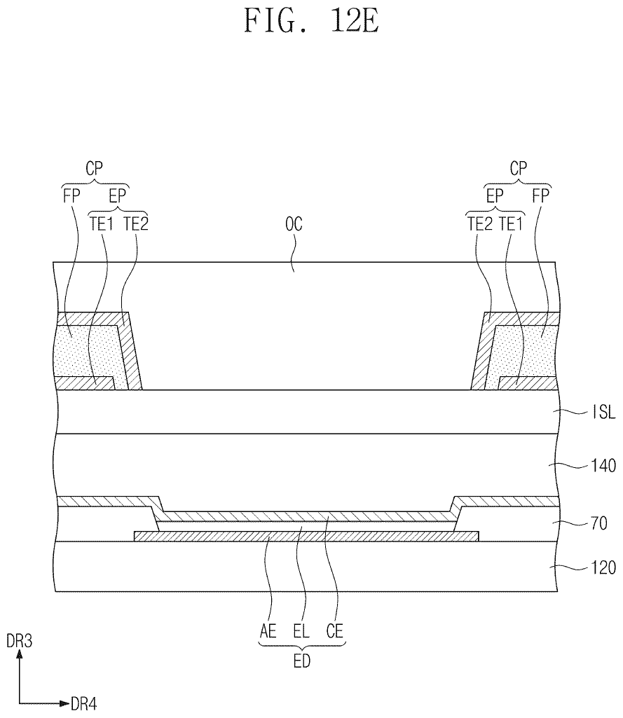

FIG. 11A is a flowchart of a method for manufacturing a display device according to an embodiment of the present disclosure. FIG. 11B is a flowchart of some operations in a method for manufacturing a display device according to an embodiment of the present disclosure. FIGS. 12A to 12E are cross-sectional views of some operations in a method for manufacturing a display device according to an embodiment of the present disclosure. Hereinafter, a method for manufacturing a display device according to an embodiment will be described with reference to FIGS. 11A to 12E, and the same/similar configurations will be described by using the same/similar reference numerals with reference to FIGS. 1A to 10, and a repeated description thereof will be omitted.

Referring to FIG. 11A, a method of manufacturing a display device according to an embodiment of the present disclosure includes an operation S100 of forming a light emitting element layer, and an operation S200 of forming an optical path control layer on the light emitting element layer. Referring to FIG. 11B, the operation S200 of forming an optical path control layer includes an operation S210 of forming a first transparent electrode through (e.g., with) a conductive material (e.g., an electrically conductive material), an operation S220 of forming a sacrificial layer through (e.g., with) an organic material on the first transparent electrode, an operation S230 of forming a second transparent electrode on the sacrificial layer, an operation S240 of forming a cavity structure between the first transparent electrode and the second transparent electrode by removing the sacrificial layer, and an operation S250 of filling an electrochromic material in the cavity structure.

Referring to FIGS. 11B and 12A together, in the method of manufacturing a display device according to an embodiment, the operation S200 of forming an optical path control layer includes an operation S210 of forming a first transparent electrode TE1 through (e.g., with) a conductive material (e.g., an electrically conductive material), and an operation S220 of forming a sacrificial layer SPP through (e.g., with) an organic material on the first transparent electrode TE1.

The first transparent electrode TE1 may be formed of an optically transparent conductive material. The first transparent electrode TE1 may be formed of a transparent conductive oxide (TCO). For example, the first transparent electrode TE1 may be formed of indium tin oxide (ITO). The first transparent electrode TE1 may be formed by patterning an electrode layer that is formed on the light emission area PXA and the non-light emission area NPXA in common, through (e.g., with) a conductive material (e.g., an electrically conductive material).

The sacrificial layer SPP is formed on the first transparent electrode TE1. The sacrificial layer SPP includes an organic material, and the organic material that forms the sacrificial layer SPP may be formed to have a set or specific thickness, and is not limited as long as it is a material that may be patterned. The sacrificial layer SPP may include a material that is removed by oxygen plasma in a removal process that will be further described herein. The sacrificial layer SPP may be applied through a printing process and/or the like to be provided in the form of an organic layer, and then may formed through patterning.

Referring to FIGS. 11B, 12A, and 12B together, in the method of manufacturing a display device according to an embodiment, the operation S200 of forming an optical path control layer includes the operation S230 of forming a second transparent electrode TE2 on the sacrificial layer SPP.

The second transparent electrode TE2 may be formed of an optically transparent conductive material. The second transparent electrode TE2 may be formed of a transparent conductive oxide (TCO). For example, the second transparent electrode TE2 may be formed of indium tin oxide (ITO). The second transparent electrode TE2 may be formed by patterning an electrode layer that is formed on the light emission area PXA and the non-light emission area NPXA in common, through (e.g., with) a conductive material (e.g., an electrically conductive material).

The second transparent electrode TE2 may be formed at least on the sacrificial layer SPP, and may be formed by following the shape of the sacrificial layer SPP. The second transparent electrode TE2 may be formed on an upper surface and a side surface of the sacrificial layer SPP. The second transparent electrode TE2 may include an upper part TE2-a that is formed on the sacrificial layer SPP, and a side wall part TE2-b that extends from the upper part TE2-a and is formed on a side of the sacrificial layer SPP.

Referring to FIGS. 11B, 12B, and 12C together, in a method of manufacturing a display device according to an embodiment, the operation S200 of forming an optical path control layer includes an operation S240 of forming a cavity CVT structure between the first transparent electrode TE1 and the second transparent electrode TE2 by removing the sacrificial layer SPP.

The sacrificial layer SPP may be removed through an oxygen (O₂) plasma ashing process. After the sacrificial layer SPP is removed, a cavity (CVT) structure is formed between the first transparent electrode TE1 and the second transparent electrode TE2. A cavity CVT may be defined by the upper part TE2-a and the side wall part TE2-b of the second transparent electrode TE2.

Referring to FIGS. 11B, 12C, and 12D together, in the method of manufacturing a display device according to an embodiment, the operation S200 of forming an optical path control layer includes an operation S250 of forming a filling pattern FP by filling an electrochromic material in the cavity (CVT) structure.

In the method of manufacturing the display device of an embodiment, the filling pattern FP may be formed by filling the cavity CVT while the electrochromic material is dispersed in an electrolyte. A mixture of the electrochromic material and the electrolyte may be injected into the cavity CVT through a capillary phenomenon. The mixture of the electrochromic material and the electrolyte may be filled in the cavity CVT through the capillary phenomenon, and a control pattern CP may be formed on the light emitting element ED and the input sensor ISL. The control pattern CP may include an electrode structure EP and a filling pattern FP.

Referring to FIGS. 11B, 12C, and 12D together, in the method of manufacturing the display device according to an embodiment, the operation S200 of forming an optical path control layer may further include an operation of forming an overcoat layer OC by providing an organic material onto the control pattern CP.

The overcoat layer OC may be formed on the control pattern CP. A portion of the overcoat layer OC may be between the adjacent control patterns CP, and may be formed to fill a space that is defined between the spaced control patterns CP. A portion of the overcoat layer OC may be on the second transparent electrode TE2. The overcoat layer OC may cover an upper portion of the control pattern CP. The overcoat layer OC may be formed directly on the control pattern CP. The overcoat layer OC may cover an upper portion of the control pattern CP to encapsulate the filling pattern FP provided in the electrode structure EP of the control pattern CP.

The overcoat layer OC may be formed through (e.g., with) an organic material, and the overcoat layer OC may include, for example, a curable polymer. The overcoat layer OC may include an optically transparent organic material. The overcoat layer OC may be formed through (e.g., with) a material having no reactivity or an extremely low reactivity with the electrochromic material and electrolyte included in the filling pattern FP of the control pattern CP. The overcoat layer OC may be formed through (e.g., with) a UV curing polymer. The overcoat layer OC may be formed by applying the UV curing polymer on the control pattern CP and then through UV curing. The overcoat layer OC may be formed on the control pattern CP to protect the control pattern CP thereunder, and provide a flat upper surface by removing a step (e.g., a surface step or defect).

According to an embodiment of the present disclosure, the display device that is operated in a mode with a limited viewing angle and a mode with an unrestricted viewing angle depending on a selection by the user or a set or predetermined regulation may be provided.

According to an embodiment of the present disclosure, a display device that is selectively operated in modes with different viewing angles without deterioration of a lateral luminance and a resolution.

Although the subject matter of the present disclosure has been described with reference to the embodiments, it will be appreciated by a person having ordinary skill in the art, to which the present disclosure pertains, that the subject matter of the present disclosure may be modified and changed within the scope of the appended claims, and equivalents thereof, without departing from the spirits and technical field of the present disclosure. Therefore, the technical scope of the present disclosure should not be limited to the detailed description of the specification, but should be determined by the appended claims, and equivalents thereof.

What is claimed is:

1. A display device comprising:
a light emitting element layer comprising a light emission area, and a non-light emission area around the light emission area; and
an optical path control layer on the light emitting element layer, and configured to control a path of light provided from the light emitting element layer,
wherein the optical path control layer comprises at least one control pattern, and
wherein the control pattern comprises:
an electrode structure that overlaps the non-light emission area, does not overlap the light emission area, and in which a cavity is defined in an interior thereof; and
a filling pattern filled in the cavity, and comprising an electrochromic material.

2. The display device of claim 1, wherein the electrode structure comprises:
a first transparent electrode provided at a lower portion of the cavity; and
a second transparent electrode around an upper portion and a side portion of the cavity.

3. The display device of claim 1, wherein the filling pattern further comprises an electrolyte, in which the electrochromic material is dispersed.

4. The display device of claim 1, wherein the optical path control layer further comprises:
an overcoat layer on the control pattern, and configured to cover an upper portion of the control pattern.

5. The display device of claim 1, wherein the control pattern comprises:
a first layer control pattern on the light emitting element layer;
a second layer control pattern on the first layer control pattern; and
a third layer control pattern on the second layer control pattern.

6. The display device of claim 5, wherein the first layer control pattern comprises a first layer electrode structure, in which a first cavity is defined, and a first layer filling pattern filled in the first cavity and comprising an electrochromic material,
wherein the second layer control pattern comprising a second layer electrode structure, in which a second cavity is defined, and a second layer filling pattern filled in the second cavity and comprising an electrochromic material, and
wherein the third layer control pattern comprises a third layer electrode structure, in which a third cavity is defined, and a third layer filling pattern filled in the third cavity and comprising an electrochromic material.

7. The display device of claim 6, wherein the first layer control pattern comprises a first power source provided to the first layer electrode structure,
wherein the second layer control pattern comprises a second power source provided to the second layer electrode structure,
wherein the third layer control pattern comprises a third power source provided to the third layer electrode structure, and
wherein the first power source, the second power source, and the third power source are distinguished from each other to be driven separately.

8. The display device of claim 1, wherein the control pattern comprises a first control pattern and a second control pattern spaced apart from each other in one direction with the light emission area therebetween.

9. The display device of claim 8, wherein a spacing distance between the first control pattern and the second control pattern in the one direction is greater than or equal to a width of the light emission area in the one direction.

10. The display device of claim 1, wherein the display device is driven to be selectively operated in any one selected from among a first mode and a second mode,
wherein, in the first mode, a separate voltage is not applied to the electrode structure, and
wherein, in the second mode, a first power source is applied to the electrode structure.

11. The display device of claim 10, wherein in the first mode, the control pattern transmits the light provided from the light emitting element layer, and
wherein, in the second mode, the control pattern shields the light provided from the light emitting element layer.

12. The display device of claim 1, wherein the electrochromic material comprises at least one selected from among a metal oxide, a metal chloride, and a graphene quantum dot.

13. The display device of claim 1, wherein the light emitting element layer comprises:
a pixel definition layer, in which a pixel opening that defines the light emission area is defined; and
a light emission layer, at least a portion of which is provided in the pixel opening, and configured to provide the light, and
wherein the control pattern overlaps the pixel definition layer on a plane.

14. The display device of claim 1, wherein the light emission area comprises a first light emission area configured to emit light of a first wavelength, a second light emission area configured to emit light of a second wavelength being different from the first wavelength, and a third light emission area configured to emit light of a third wavelength being different from the first wavelength and the second wavelength, and
wherein the control pattern overlaps between the first light emission area and the second light emission area, and between the second light emission area and the third light emission area on a plane.

15. The display device of claim 1, further comprising:
an input sensor between the optical path control layer and the light emitting element layer.

16. The display device of claim 15, wherein the optical path control layer is directly on the input sensor.

17. An electronic device comprising:
a light emitting element layer comprising a light emission area, and a non-light emission area around the light emission area; and
an optical path control layer on the light emitting element layer,
wherein the optical path control layer comprises:
at least one control pattern; and
an overcoat layer that covers an upper portion of the control pattern, and
wherein the control pattern comprises:
an electrode structure that overlaps the non-light emission area, and in which a cavity is defined in an interior thereof; and
a filling pattern filled in the cavity, and comprising an electrochromic material.

18. A method for manufacturing a display device, the method comprising:
forming a light emitting element layer; and
forming an optical path control layer on the light emitting element layer,
wherein the forming of the optical path control layer comprises:
forming a first transparent electrode with a conductive material;
forming a sacrificial layer on the first transparent electrode with an organic material;
forming a second transparent electrode on the sacrificial layer;
forming a cavity structure between the first transparent electrode and the second transparent electrode by removing the sacrificial layer; and
filling an electrochromic material in the cavity structure.

19. The method of claim 18, wherein the forming of the optical path control layer further comprises:
forming an overcoat layer by providing an organic material on the second transparent electrode.

20. The method of claim 18, wherein in the filling of the electrochromic material, the electrochromic material is dispersed in an electrolyte to be filled in the cavity structure through a capillary phenomenon.
